(19) United States
(12) Patent Application Publication
(10) Pub. No.: US 2026/0026252 A1
(43) Pub. Date: Jan. 22, 2026

(54) METHOD OF PROVIDING DISPLAY DEVICE, ELECTRONIC DEVICE INCLUDING THE DISPLAY DEVICE AND METHOD OF PROVIDING THE SAME

(71) Applicant: Samsung Display Co., Ltd., Yongin-si (KR)

(72) Inventors: HYEMIN LEE, Yongin-si (KR); BYEONGJUN LEE, Yongin-si (KR); JINHO HYUN, Yongin-si (KR)

(21) Appl. No.: 19/173,123

(22) Filed: Apr. 8, 2025

(30) Foreign Application Priority Data
Jul. 16, 2024 (KR) 10-2024-0093604

(51) Int. Cl. H10K 71/40; H10K 59/12

(52) U.S. Cl. CPC H10K 71/40; H10K 59/1201

(57) ABSTRACT

A method of providing an electronic device includes providing a display device including a display region and a non-display region which extends from the display region, and a substrate in the display region and in the non-display region, providing an organic material on the substrate in the display region and the non-display region, spreading the organic material to provide an organic material layer in the display region and the non-display region; and irradiating the organic material layer with light to provide a cured organic material layer in the display region and the non-display region. A temperature of gas or heat provided to spread the organic material in the display region is different from a temperature of gas or heat provided in the non-display region.

This application claims priority to Korean Patent Application No. 10-2024-0093604, filed on Jul. 16, 2024, and all the benefits accruing therefrom under 35 U.S.C. § 119, the entire contents of which are hereby incorporated by reference.

### BACKGROUND

### (1) Field

The present disclosure herein relates to a method for manufacturing (or providing) a display device, and an electronic device including the same.

### (2) Description of the Related Art

A display device of an electronic device such as a television, a monitor, a smart phone and a tablet, provides an image to a user of the electronic device. The display device includes a display panel for displaying the image. Various display panels, such as a liquid crystal display panel, an organic light emitting display panel, an electro wetting display panel, and an electrophoretic display panel, are being developed as the display panel of electronic devices.

### SUMMARY

The present disclosure provides a method for manufacturing (or providing) a display device having improved flatness of an organic film disposed on a display region, and an electronic device including the display device.

The present disclosure also provides a method for manufacturing (or providing) a display device having a reduced area of an organic film disposed on a non-display region, and an electronic device including the display device.

An embodiment of the invention provides a method for manufacturing an electronic device including a display device, the method including disposing a nozzle on a substrate of the display device which includes a base layer, a circuit layer, and a display element layer sequentially stacked, thereby providing an organic material, providing a gas on a lower surface of the base layer, thereby spreading the organic material, and irradiating the organic material with light, thereby curing the organic material, where the substrate includes a display region and a non-display region extending from the display region, where the temperature of a gas provided in the display region and the temperature of a gas provided in the non-display region are different from each other.

In an embodiment of the invention, a method for manufacturing (or providing) an electronic device including a display device includes preparing a substrate of the display device including a display region and a non-display region adjacent to the display region, where a base layer, a circuit layer disposed on the base layer, a display element layer disposed on the circuit layer, and a first inorganic film disposed on the display element layer are sequentially stacked on the substrate, disposing a plurality of nozzles on the substrate, thereby providing an organic material on the substrate, applying heat to the substrate, thereby spreading the organic material provided on the substrate, and irradiating the organic material with light, thereby curing the organic material, where the temperature of the display region is higher than the temperature of the non-display region.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain the invention. In the drawings:

FIG. 1 is a perspective view of a display device according to an embodiment of the invention;

FIG. 2 is a cross-sectional view of the display device illustrated in FIG. 1;

FIG. 3 is a cross-sectional view of a display panel illustrated in FIG. 2 of the invention;

FIG. 4 is a cross-sectional view of a display panel and an input sensor according to an embodiment of the invention;

FIG. 5 is a plan view of a display panel according to an embodiment of the invention;

FIG. 6 is a plan view of an input sensor according to an embodiment of the invention;

FIG. 7A is an enlarged cross-sectional view corresponding to line I-I′ illustrated in FIG. 5;

FIG. 7B is an enlarged cross-sectional view of a first region AA′ illustrated in FIG. 7A;

FIGS. 8A to 8H are cross-sectional views of a method for providing a stacked structure including a display panel and an input sensor illustrated in FIG. 7A;

FIG. 9 is a block diagram illustrating an electronic device according to an embodiment of the present disclosure; and

FIG. 10 is a schematic view of electronic devices according to embodiments of the present disclosure.

### DETAILED DESCRIPTION

In the present disclosure, when an element (or a region, a layer, a portion, and the like) is referred to as being related to another element such as being “on,” “connected to,” or “coupled to” another element, it means that the element may be directly disposed on/connected to/coupled to the other element, or that a third element may be disposed therebetween. In contrast, when an element (or a region, a layer, a portion, and the like) is referred to as being related to another element such as being “directly on,” “directly connected to,” or “directly coupled to” another element, it means that no third element is disposed therebetween.

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements. Also, in the drawings, the thickness, the ratio, and the dimensions of elements are exaggerated for an effective description of technical contents.

The terms of a singular form may include plural forms unless the context clearly indicates otherwise. Within the Figures and the text of the disclosure, a reference number indicating a singular form of an element may also be used to reference a plurality of the element. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” The term “and/or” includes all combinations of one or more of which associated components may define.

The terms “first,” “second,” and the like may be used for describing various elements, but the elements should not be construed as being limited by the terms. The terms are used only for the purpose of distinguishing one component from the other. For example, a first element may be referred to as a second element, and a second element may also be referred to as a first element in a similar manner without departing the scope of rights of the present invention. As used herein, for example, an expression of 2-1, 2-2, etc. may indicate a first-second element, a second-second element, etc.

In addition, terms such as “below,” “lower,” “above,” “upper,” and the like are used to describe the relationship of the components shown in the drawings. The terms are used as a relative concept and are described with reference to the direction indicated in the drawings.

It should be understood that the term “comprise,” or “have” is intended to specify the presence of stated features, integers, steps, operations, elements, components, or combinations thereof in the disclosure, but do not preclude the presence or addition of one or more other features, integers, steps, operations, elements, components, or combinations thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which the present invention pertains. It is also to be understood that terms such as terms defined in commonly used dictionaries should be interpreted as having meanings consistent with the meanings in the context of the related art, and should not be interpreted in too ideal a sense or an overly formal sense unless explicitly defined herein.

Hereinafter, embodiments of the present invention will be described with reference to the accompanying drawings.

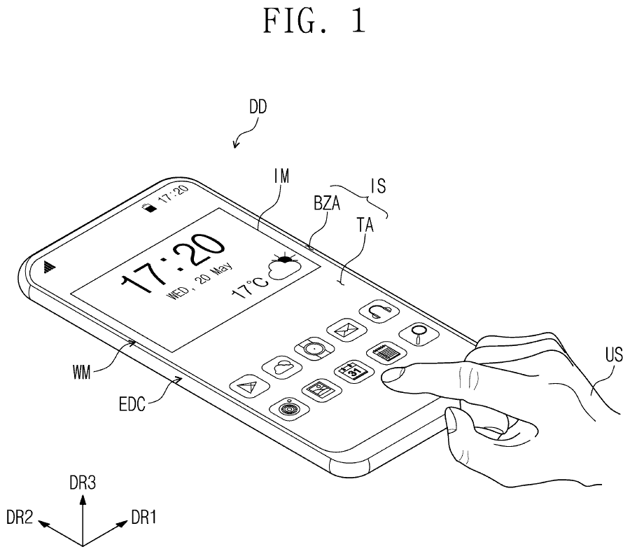

FIG. 1 is a perspective view of a display device DD according to an embodiment of the invention.

Referring to FIG. 1, the display device DD may be an electronic device activated in response to an electrical signal and may display images by such activation. For example, the display device DD may be included in a large-sized electronic device such as a television and an external billboard, and also in a small-and-medium-sized electronic device such as a monitor, a mobile phone, a tablet computer, a navigation system unit, and a game console. Meanwhile, embodiments of the display device DD are exemplary, and the display device DD and the electronic device in which such display device DD is used is not limited to any one thereof without departing from the concept of the present invention. In the present embodiment, a mobile phone is illustrated as an example of the display device DD.

The display device DD of an embodiment may be flexible. Being “flexible” refers to having properties of being able to be bent, folded, rolled, etc., which may include from a structure of being completely folded to a structure of being able to be bent to a degree of a few nanometers. For example, a flexible display device DD may include a curved electronic device or a foldable electronic device. However, the embodiment of the invention is not limited thereto, and the display device DD may be rigid.

The display device DD may have, on a plane, a rectangular shape which has long sides extended in (or along) a first direction DR1 and short sides extended in (or along) a second direction DR2 which crosses the first direction DR1. However, the embodiment of the invention is not limited thereto, and the display device DD may have various shapes on a plane, such as a circular shape and a polygonal shape.

The display device DD may display an image IM toward a third direction DR3 on a display surface IS which is parallel to each of the first direction DR1 and the second direction DR2. That is, the display surface IS may be in a plane defined by the first direction DR1 and the second direction DR2 crossing each other. The image IM provided from the display device DD may include both a moving image and a still image. FIG. 1 illustrates a watch window and icons as an example of the image IM.

The display surface IS on which the image IM is displayed may correspond to a front surface of the display device DD, and the display surface IS may also correspond to a front surface of a window WM. Hereinafter, the front surface of the window WM will be denoted by the same symbol as that of display surface IS and described. Meanwhile, FIG. 1 exemplarily illustrates a planar display surface IS, but the embodiment of the invention is not limited thereto, and the display surface IS of the display device DD may include a curved surface bent from at least one side of a planar surface.

The front surface (or upper surface) and the rear surface (or lower surface) of members constituting the display device DD may oppose each other in the third direction DR3, and a normal direction of each of the front surface and the rear surface may substantially be parallel to the third direction DR3. A separation distance between the front surface and the rear surface, which is defined along the third direction DR3, may correspond to the thickness of a member (or unit). That is, a thickness of the display device DD and various components or layers thereof may be defined along the third direction DR3, e.g., a thickness direction of the display device DD.

In the present disclosure, “on a plane” may be defined as a state viewed in the third direction DR3. In the present disclosure, “on a cross-section” may be defined as a state viewed in the first direction DR1 or in the second direction DR2 (e.g., in a direction along a plane which is defined by the first direction DR1 and the second direction DR2 crossing each other. Meanwhile, the direction indicated by each of the first to third directions DR1, DR2, and DR3 is a relative concept, and may be converted into a different direction.

The display device DD may sense an external input applied from the outside (e.g., from outside of the display device DD). The external input may include various forms of inputs provided from the outside of the display device DD. For example, the external input may include force, pressure, temperature, light, or the like. The external input may include not only an input which comes into contact with an input tool like (e.g., a contact by a body part like a hand of a user US, or by a pen) with the display device DD, but also an input from the input tool (e.g., hovering) applied in close proximity to the display device DD, or adjacent thereto by a predetermined distance.

In the present embodiment, the external input is exemplarily illustrated as being a touch input by the hand of the user US applied to the front surface of the display device DD. However, this is merely an example, and the external input may include all input capable of changing capacitance (e.g., electrical capacitance) and is not limited to any one input. In addition, a region of the display device DD for sensing an external input is not limited to the front surface of the display device DD, and depending on the structure, the display device DD may sense an input of the user US applied to the side surface or rear surface of the display device DD.

The display device DD may include the window WM and a case EDC. The window WM and the case EDC may be coupled to each other to configure the outer appearance of the display device DD, and may provide an internal space in which components of the display device DD may be accommodated. For example, components of the display device DD, such as a display panel, an input sensor, a protective member, and an electronic module, may be accommodated between the window WM and the case EDC.

The front surface IS (or a display surface) of the window WM may be divided into a transmissive region TA and a bezel region BZA. The transmissive region TA may be an optically clear region and light may be transmittable therethrough. Accordingly, the image IM provided by the display device DD may be transmitted through the transmissive region TA, and the user US may visually recognize the image IM. In the present embodiment, the transmissive region TA is illustrated in a quadrangular shape with rounded vertices in the plan view, but this is exemplarily illustrated, and the transmissive region TA may have various planar shapes.

The bezel region BZA may be adjacent to the transmissive region TA. For example, the bezel region BZA may be disposed on an outer side of the transmissive region TA, and may surround the transmissive region TA in the plan view. Accordingly, the planar shape of the transmissive region TA may substantially be defined by the bezel region BZA. However, this is exemplarily illustrated, and the bezel region BZA may be adjacent to only one side of the transmissive region TA, or may be omitted. In addition, the bezel region BZA may be disposed on a side surface of the display device DD which extends from the front surface, not on the front surface thereof. A boundary may be defined between the transmissive region TA and the bezel region BZA.

The bezel region BZA may be a region (or planar area) which has a predetermined color and blocks light. The bezel region BZA may prevent the components of the display device DD, which are disposed overlapping the bezel region BZA, from being be visually recognized from the outside.

The case EDC may include glass, plastic, or a metal material having relatively high rigidity. The case EDC may absorb an impact applied from the outside, or may prevent foreign substances/moisture and the like from penetrating from the outside to protect the components of the display device DD accommodated inside of the case EDC. The case EDC of an embodiment may be provided in a form in which a plurality of receiving members are coupled to each other to form the case EDC.

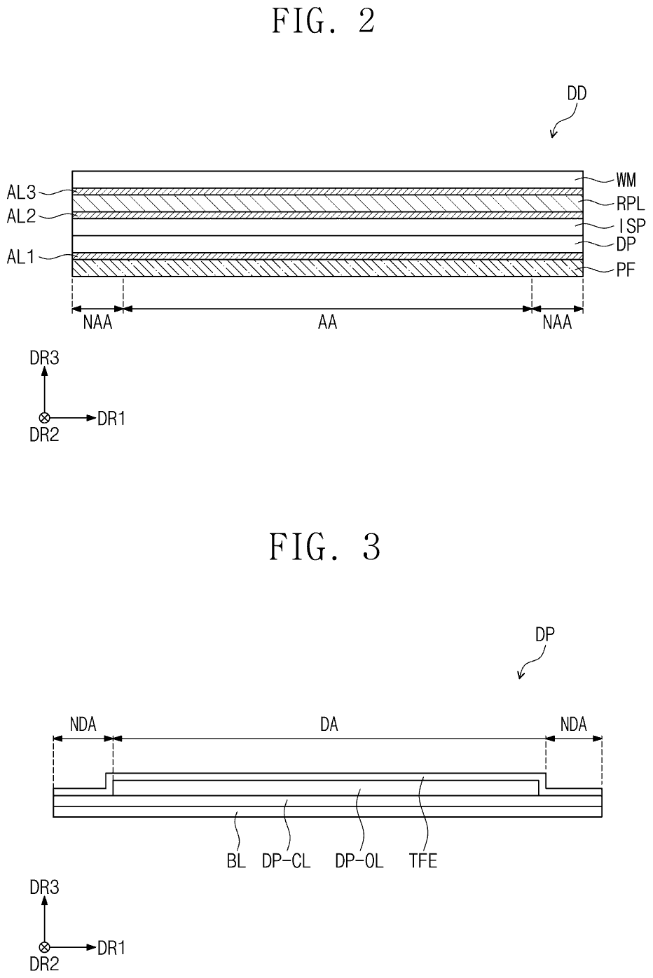

FIG. 2 is a cross-sectional view of the display device DD illustrated in FIG. 1.

For convenience of description, a form in which the components of the display device DD are stacked is schematically illustrated.

Referring to FIG. 2, the display device DD may include the display panel DP as an image generating layer, the input sensor ISP as an input sensing layer, a protective member PF as a protective layer, a reflection prevention layer RPL, the window WM, and an adhesive layer provided in plural such as adhesive layers AL1, AL2, and AL3. Components of the display device DD disposed below the window WM may be disposed between the window WM and the case EDC, which are described above and accommodated inside the case EDC.

The display device DD may include an active region AA and a peripheral region NAA. The active region AA may be a region which is electrically activated, such as to generate light, display an image, etc. The display device DD may display an image IM through the active region AA, and may sense an external input applied at the active region AA. The active region AA may correspond to the transmissive region TA (see FIG. 1) described above.

The peripheral region NAA may be a region in which elements or components for activating the active region AA are disposed. The peripheral region NAA may be adjacent to an outer side of the active region AA. For example, the peripheral region NAA may surround the active region AA. The peripheral region NAA may correspond to the bezel region BZA (see FIG. 1) described above.

Meanwhile, as used herein, when “a region/portion corresponds to a region/portion,” it means “they overlap each other,” and is not limited to having the same area and/or the same shape. As overlapping, regions or portions are arranged along the third direction DR3, or a thickness direction.

The display panel DP may generate and/or display an image IM in response to an electrical signal. The display panel DP according to an embodiment may be a light emitting-type display panel which generates and self-emits light, but is not particularly limited. For example, the display panel DP may be an organic light emitting display panel, an inorganic light emitting display panel, or a quantum dot light emitting display panel. A light emitting layer of the organic light emitting display panel may include an organic light emitting material, and a light emitting layer of the inorganic light emitting display panel may include an inorganic light emitting material. A light emitting layer of the quantum-dot light emitting display panel may include a quantum dot, a quantum load, and the like. Hereinafter, the display panel DP will be described as an organic light emitting display panel.

The input sensor ISP may be disposed on the display panel DP. The input sensor unit ISP may be directly disposed on the display panel DP without a separate adhesive member. That is, after the display panel DP is formed (or provided), the input sensor ISP may be formed through a continuous process on a base surface provided by a front surface of the display panel DP. However, the embodiment of the invention is not limited thereto, and the input sensor ISP may be manufactured (or provided) in the form of a panel through a separate process distinguished from a process of the display panel DP, and then may be attached to the display panel DP by an intervening member such as an adhesive member.

The input sensor ISP is capable of sensing an external input applied from the outside of the display device DD, and obtaining coordinate information of the external input. The input sensor ISP may be driven by various methods, such as a capacitive method, a resistive film method, an infrared method, or a pressure method, but the embodiment of the invention is not limited thereto.

The protective member PF may be disposed on a rear surface of the display panel DP which is opposite to the front surface thereof. The protective member PF may include at least one of a protective film layer, an impact absorbing layer and a support plate layer which protect the display panel DP from an external impact.

The protective film layer may include a polymer material having flexibility, such as polyethylene terephthalate or polyimide, and may protect the display panel DP. The impact absorbing layer may include a material such as a sponge, a foam, or a urethane resin, and may absorb an impact applied to the display panel DP. The support plate layer may include a metal material having relatively high rigidity, such as stainless steel, aluminum, or an alloy thereof, and may support a lower portion of the display panel DP. Meanwhile, the form of the protective member PF is not limited to any one embodiment as long as it can protect the display panel DP.

The reflection prevention layer RPL may be disposed on the input sensor ISP. The reflection prevention layer RPL may reduce the reflectance of external light incident from an upper side of the display device DD.

In an embodiment, the reflection prevention layer RPL may include a phase retarder and/or a polarizer. The phase retarder may include a λ/2 phase retarder and/or λ/4 phase retarder. The polarizer may include a film-type or a liquid crystal coating-type polarizer. The film-type polarizer may include a stretchable synthetic resin film, and the liquid crystal coating-type polarizer may include liquid crystals arranged in a predetermined arrangement. However, the embodiment of the invention is not limited thereto, and the phase retarder and the polarizer may be implemented in the form of one polarizing film.

In an embodiment, the refection prevention layer RPL may include color filters. The color filters may be disposed corresponding to the arrangement and emission colors of pixels included in the display panel DP. The color filters may receive external light and may filter the external light into the same color as the color emitted by the pixels. The reflection prevention layer RPL may further include a black matrix disposed adjacent to the color filters.

In an embodiment, the refection prevention layer RPL may include an offset interference structure. For example, the offset interference structure may include a first reflection layer and a second reflection layer which are disposed on different layers from each other. First reflected light reflected from the first reflection layer and second reflected light reflected from the second reflection layer may be offset and interfered, and accordingly, the reflection prevention layer RPL may reduce the reflectance of external light.

The window WM may be disposed on the display panel DP. The window WM may have a planar shape corresponding to the planar shape of the display panel DP. The window WM may cover the entire outer display side of the display panel DP, and may protect the display panel DP from an external impact and a scratch.

The window WM may include an optically clear insulating material. For example, the window WM may include glass, sapphire, or a polymer. The window WM may have a single-layered structure or multi-layered structure. The window WM may further include functional layers such as a fingerprint prevention layer, a phase control layer, and a hard coating layer, which are disposed on an optically clear substrate.

The adhesive layers may include a first adhesive layer AL1, a second adhesive layer AL2, and a third adhesive layer AL3. The first adhesive layer AL1 may be disposed between the display panel DP and the protective member PF, and the display panel DP and the protective member PF may be bonded to each other by the first adhesive layer AL1. The second adhesive layer AL2 may be disposed between the reflection prevention layer RPL and the input sensor ISP, and the reflection prevention layer RPL and the input sensor ISP may be bonded to each other by the second adhesive layer AL2. The third adhesive layer AL3 may be disposed between the window WM and the reflection prevention layer RPL, and the window WM and the reflection prevention layer RPL may be bonded to each other by the third adhesive layer AL3. Meanwhile, in an embodiment, at least one of the first to third adhesive layers AL1, AL2, and AL3 may be omitted.

Each of the first to third adhesive layers AL1, AL2, and AL3 may include a clear adhesive such as an optically clear adhesive (OCA) film, an optically clear resin (OCR), or a pressure sensitive adhesive (PSA) film. However, types of an additive included in the first to third adhesive layers AL1, AL2, and AL3 are not limited thereto.

Meanwhile, the display device DD may further include an electronic module including various functional modules for operating the display panel DP, or a power supply module for supplying power necessary for the display device DD. For example, the display device DD may include a camera module as an example of the electronic module.

FIG. 3 is a cross-sectional view of the display panel illustrated in FIG. 2 of the invention.

Referring to FIG. 3, the display panel DP may include a base layer BL, a circuit layer DP-CL, a display element layer DP-OL, and an encapsulation layer TFE.

The base layer BL may provide a base surface on which the circuit layer DP-CL is disposed. The base layer BL may be provided as a rigid substrate, but is not limited thereto, and may be provided as a flexible substrate.

The base layer BL may include a display region DA and a non-display region NDA. The display region DA of the display panel DP may be a region activated in response to an electrical signal and displaying an image. According to an embodiment, the display region DA of the display panel DP may correspond to the transmissive region TA (see FIG. 1) of the window WM (see FIG. 1) and the active region AA (see FIG. 2) of the display device DD (see FIG. 2). One or more of these regions may be considered a display area having a planar area at which components are activated, an image IM is displayed, light is transmitted, etc.

The non-display region NDA may be a region in which a driving circuit or a driving line for driving elements disposed in the display region DA, various signal lines for providing an electrical signal, pads, and the like are disposed. According to an embodiment, the non-display region NDA of the display panel DP may correspond to the bezel region BZA (see FIG. 1) of the window WM (see FIG. 1) and the peripheral region NAA (see FIG. 2) of the display device DD. One or more of these regions may be considered a non-display area having a planar area at which an image IM is not displayed, without being limited thereto. Visual recognition from the outside of components of the display panel DP disposed in the non-display region NDA may be prevented by the bezel region BZA.

The circuit layer DP-CL may be disposed on the base layer BL. The circuit layer DP-CL may include at least one insulating layer, and driving elements, signal lines, and signal pads.

The display element layer DP-OL may be disposed on the circuit layer DP-CL. The display element layer DP-OL may include light emitting elements disposed overlapping the display region DA. The light emitting elements of the display element layer DP-OL may be electrically connected to driving elements of the circuit layer DP-CL, and provide source light through the display region DA in response to a signal of a driving element.

The encapsulation layer TFE may be disposed on the display element layer DP-OL, and may encapsulate the light emitting elements. The encapsulation layer TFE may include a plurality of insulating films. The insulating films of the encapsulation layer TFE may be disposed to improve optical efficiency of a light emitting element or to protect the light emitting element.

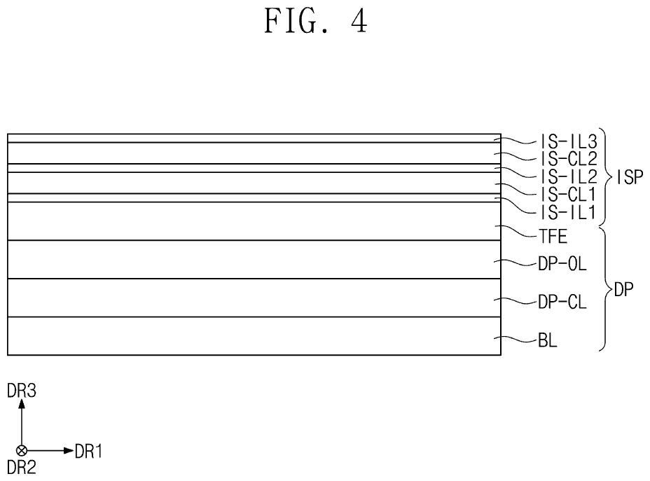

FIG. 4 is a cross-sectional view of a display panel DP and an input sensor ISP according to an embodiment of the invention.

Referring to FIG. 4, the input sensor ISP may include a first sensing insulating layer IS-IL1, a first conductive layer IS-CL1, a second sensing insulating layer IS-IL2, a second conductive layer IS-CL2, and a third sensing insulating layer IS-IL3. The first sensing insulating layer IS-IL1 of the input sensor ISP may be disposed directly on the encapsulation layer TFE. Meanwhile, in the input sensor ISP of an embodiment, the first sensing insulating layer IS-IL1 may be omitted.

Each of the first conductive layer IS-CL1 and the second conductive layer IS-CL2 may have a single-layered structure and/or multi-layered structure. A conductive layer having a multi-layered structure may include at least two or more layers among a clear (e.g., optically transmissive) conductive layer and a metal layer. The conductive layer having a multi-layered structure may include metal layers including different metals from each other.

The first conductive layer IS-CL1 and the second conductive layer IS-CL2 may include, as a clear conductive layer, at least one of indium tin oxide (ITO), indium zinc oxide (IZO), zinc oxide (ZnO), indium tin zinc oxide (ITZO), PEDOT, a metal nanowire and graphene. The first conductive layer IS-CL1 and the second conductive layer IS-CL2 may include, as a metal layer, molybdenum, silver, titanium, copper, aluminum, or an alloy thereof. For example, each of the first conductive layer IS-CL1 and the second conductive layer IS-CL2 may have a three-layered structure composed of titanium/aluminum/titanium. A metal layer having relatively high durability and low (light) reflectance may be applied to an outer layer of a conductive layer, and a metal layer having high electrical conductivity may be applied to an inner layer of the conductive layer.

The first conductive layer IS-CL1 and the second conductive layer IS-CL2 may include sensing patterns of the input sensor ISP, which will be described later. The sensing patterns may include sensing electrodes and sensing signal lines which are connected to the sensing electrodes.

Each of the first to third sensing insulating layers IS-IL1, IS-IL2, IS-IL3 may include an inorganic layer. The inorganic layer may include at least one of aluminum oxide, titanium oxide, silicon oxide, silicon oxynitride, zirconium oxide and hafnium oxide. However, materials of the first to third sensing insulating layers IS-IL1, IS-IL2, and IS-IL3 are not limited to the above-described examples, and the first to third sensing insulating layers IS-IL1, IS-IL2, and IS-IL3 may include an organic layer. For example, in an embodiment, each of the first sensing insulating layer IS-IL1 and the second sensing insulating layer IS-IL2 may include an inorganic layer, and the third sensing insulating layer IS-IL3 may include an organic layer. However, the embodiment of the invention is not necessarily limited thereto.

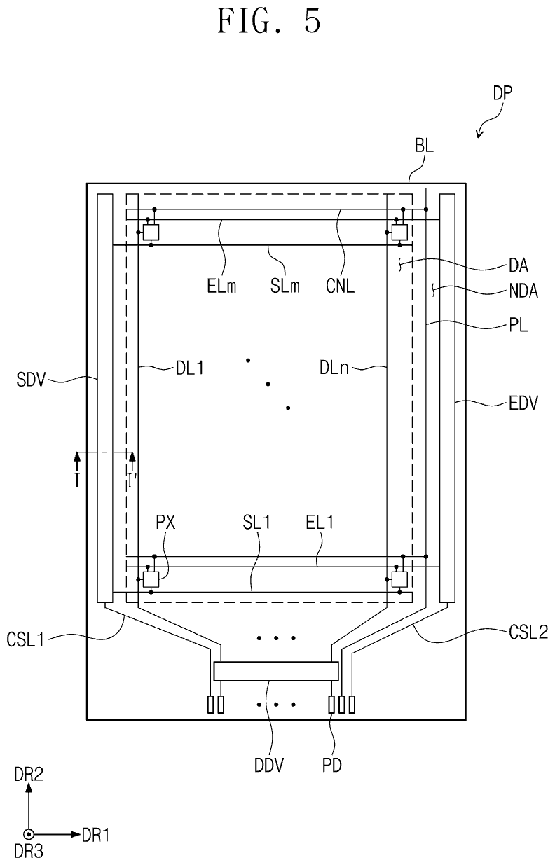

FIG. 5 is a plan view of a display panel DP according to an embodiment of the invention.

Illustratively, FIG. 5 illustrates some of the components of the display panel DP on a plane which is defined by the first direction DR1 and the second direction DR2 intersecting each other.

Referring to FIG. 5, the display panel DP may include the base layer BL, a pixel PX provided in plural including a plurality of pixels PX, a signal line provided in plural including a plurality of signal lines electrically connected to the pixels PX, a scan driver SDV, a data driver DDV, and an emission driver EDV.

As described above, the base layer BL may include the display region DA and the non-display region NDA. The base layer BL may provide a base surface on which electrical elements and lines (e.g., signal lines, conductive lines, etc.) of the display panel DP are disposed. FIG. 5 schematically illustrates that the shape of the base layer BL on a plane is a rectangular shape parallel to each of the first direction DR1 and the second direction DR2, but the embodiment of the invention is not limited thereto. The base layer BL may be designed in various shapes depending on the structure of the display device DD. The base layer BL may define an overall planar area of the display panel DP, without being limited thereto.

Each of the pixels PX may include a pixel driving circuit composed of a light emitting element, a plurality of transistors (e.g., a switching transistor, a driving transistor, etc.) connected to the light emitting element, and a capacitor. Each of the pixels PX may emit light in response to an electrical signal applied to the pixel PX. The pixels PX may be disposed in the display region DA. However, this is exemplarily illustrated, and some of components of the pixels PX may include a thin film transistor disposed in the non-display region NDA, and the embodiment of the invention is not limited to any one embodiment.

Each of the scan driver SDV, the data driver DDV, and the emission driver EDV may be disposed in the non-display region NDA of the display panel DP. In an embodiment, each of the scan driver SDV and the emission driver EDV may be disposed in the non-display region NDA adjacent to long sides of the base layer BL. The data driver DDV may be disposed in the non-display region NDA adjacent to a short side of the base layer BL. However, the embodiment of the invention is not limited thereto, and in an embodiment, at least one of the scan driver SDV, the data driver DDV and the emission driver EDV may overlap the display region DA. Accordingly, the area of the non-display region NDA may be reduced, and a display device having a reduced bezel area may be implemented.

The data driver DDV may be provided in the form of an integrated circuit chip defined as a driving chip, and mounted in the non-display region NDA of the display panel DP. However, the embodiment of the invention is not limited thereto, and the data driver DDV may be mounted on a separate flexible circuit board connected to the display panel DP at the non-display region NDA thereof and electrically connected to the display panel DP at the non-display region NDA thereof.

Although not illustrated, in an embodiment, at least a portion of the non-display region NDA of the display panel DP may be bent, such as relative to the DR1-DR2 plane. For example, a portion of the display panel DP may be bent such that a portion of the non-display region NDA in which the data driver DDV is disposed overlaps a portion of the display panel DP in which the display region DA is defined. However, the embodiment of the invention is not limited thereto, and the data driver DDV may be mounted on a separate flexible circuit board, and the flexible circuit board may be bent and connected to the display panel DP at an end thereof. Accordingly, a planar area of the bezel area of the display device DD may be reduced.

The plurality of signal lines may include scan lines SL1 to SLm, data lines DL1 to DLn, emission lines EL1 to ELm, first and second control lines CSL1 and CSL2, a power line PL, and connection lines CNL. Here, ‘m’ and ‘n’ represent natural numbers.

Each of the pixels PX may be connected to a corresponding scan line among the scan lines SL1 to SLm, may be connected to a corresponding data line among the data lines DL1 to DLn, and may be connected to a corresponding emission line among the emission lines EL1 to ELm. Meanwhile, depending on a configuration of the pixel driving circuit of the pixels PX, more types of signal lines may be provided in the display panel DP.

The scan lines SL1 to SLm may be extended in the first direction DR1 and connected to the scan driver SDV. The data lines DL1 to DLn may be extended in the second direction DR2 and connected to the data driver DDV. The emission lines EL1 to ELm may be extended in the first direction DR1 and connected to the emission driver EDV. As being extended in a direction, a feature may have a major dimension defined along such direction such as to define an extension direction of the feature.

The power line PL may be extended in the second direction DR2 and disposed in the non-display region NDA. The power line PL may be disposed between the display region DA and the emission driver EDV. However, the embodiment of the invention is not limited thereto, and the power line PL may be disposed between the display region DA and the scan driver SDV.

The connection lines CNL may be extended in the first direction DR1 and arranged in the second direction DR2 to be connected to the power line PL and the pixels PX. The connection lines CNL may be disposed on a different layer from the power line PL among layers along a thickness direction, and electrically connected thereto. However, the embodiment of the invention is not limited thereto, and the connection lines CNL may be formed as one body with the power line PL, on the same layer. A first voltage may be applied to the pixels PX through the power line PL and the connection lines CNL which are connected to each other.

The first control line CSL1 may be connected to the scan driver SDV. The second control line CSL2 may be connected to the emission driver EDV.

A pad PD provided in plural including pads PD may be disposed adjacent to a lower end of the non-display region NDA, that is, an end portion of the display panel DP. The pads PD may be disposed more adjacent to (e.g., closer to) a lower end of the display panel DP than the data driver DDV. The pads PD may be arranged along the first direction DR1, along an outer edge of the display panel DP. The display device DD may include a circuit board including a timing controller for controlling the operation of the scan driver SDV, the data driver DDV and the emission driver EDV, and a voltage generator for generating a voltage. The pads PD may be portions of the display panel DP at which the display panel DP is connected to an external component such as the circuit board of the display device DD.

The pads PD may each be connected to a corresponding signal line among the plurality of signal lines. The power line PL and the first and second control lines CSL1 and CSL2 may be connected to the pads PD. The data lines DL1 to DLn may be connected to corresponding pads PD through the data driver DDV. For example, the data lines DL1 to DLn may be connected to the data driver DDV, and the data driver DDV may be connected to pads PD respectively corresponding to the data lines DL1 to DLn.

The scan driver SDV may generate scan signals in response to a scan control signal. The scan signals may be applied to the pixels PX through the scan lines SL1 to SLm. The data driver DDV may generate data voltages corresponding to image signals in response to a data control signal. The data voltages may be applied to the pixels PX through the data lines DL1 to DLn. The emission driver EDV may generate emission signals in response to an emission control signal. The emission signals may be applied to the pixels PX through the emission lines EL1 to ELm.

The pixels PX may be provided with the data voltages in response to the scan signals. The pixels PX may display an image by emitting light of luminance corresponding to the data voltages in response to the emission signals. The emission duration of the pixels PX may be controlled by the emission signals. Accordingly, the display panel DP may output an image through the display region DA by the pixels PX.

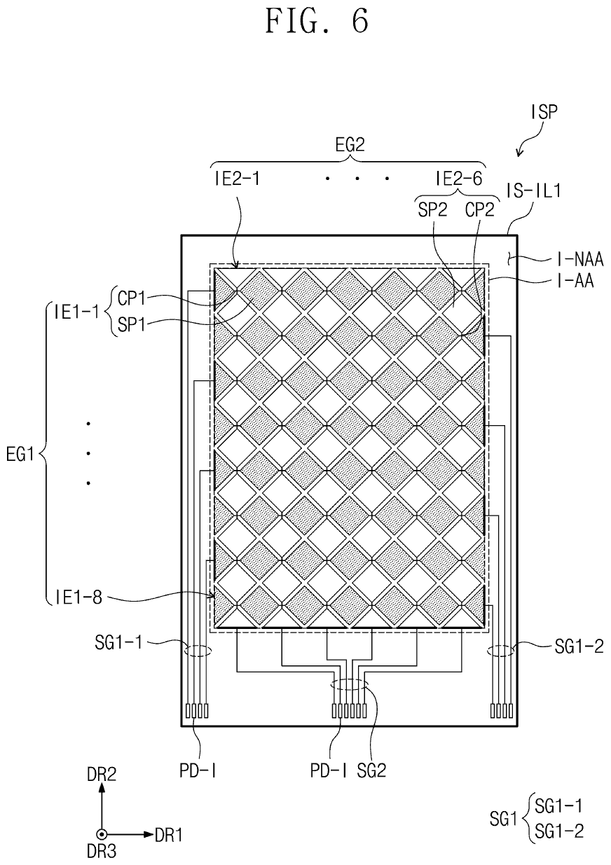

FIG. 6 is a plan view of an input sensor ISP according to an embodiment of the invention.

Illustratively, FIG. 6 illustrates some of components of the input sensor ISP on a plane.

Referring to FIG. 4 and FIG. 6, the input sensor ISP may include the first sensing insulating layer IS-IL1, the first conductive layer IS-CL1, the second sensing insulating layer IS-IL2, the second conductive layer IS-CL2, and the third sensing insulating layer IS-IL3. The first conductive layer IS-CL1 and the second conductive layer IS-CL2 of the input sensor ISP may include a first electrode group EG1, a second electrode group EG2, a first sensing signal line group SG1 connected to the first electrode group EG1, and a second sensing signal line group SG2 connected to the second electrode group EG2. The first electrode group EG1 and the second electrode group EG2 may be disposed in a sensing region I-AA, and the first sensing signal line group SG1 and the second sensing signal line group SG2 may be disposed in a line region I-NAA.

Meanwhile, the planar shape of the first electrode group EG1 and the planar shape of the second electrode group EG2 illustrated in FIG. 6 are exemplary, and the planar shapes thereof may be designed in various ways according to the structure or use of the display device DD (see FIG. 1).

The first sensing insulating layer IS-IL1 may provide a base surface on which electrodes and lines of the input sensor ISP are disposed. The first sensing insulating layer IS-IL1 may define an overall planar area of the input sensor ISP, without being limited thereto. However, in an embodiment, the first sensing insulating layer IS-IL1 of the input sensor ISP may be omitted, and in this case, the electrodes and the lines of the input sensor ISP may be disposed on the base surface provided by the display panel DP. FIG. 6 schematically illustrates that the shape of the first sensing insulating layer IS-IL1 on a plane is a rectangular shape parallel to each of the first direction DR1 and the second direction DR2, but the embodiment of the invention is not limited thereto. The shape of the first sensing insulating layer IS-IL1 may be designed in various shapes depending on the shape of the base layer BL (see FIG. 5) of the display panel DP (see FIG. 5).

The first sensing insulating layer IS-IL1 may include the sensing region I-AA and the line region I-NAA. The sensing region I-AA may be a region for sensing an external input provided from the outside of the display device DD. The line region I-NAA may be a region in which lines for providing an electrical signal for activation of the sensing region I-AA are disposed. The sensing region I-AA may correspond to the display region DA (see FIG. 5) of the display panel DP (see FIG. 5), and the line region I-NAA may correspond to the non-display region NDA (see FIG. 5) of the display panel DP.

In the present embodiment, the input sensor ISP may be a sensor driven in a capacitive manner. The input sensor ISP may obtain information on an external input through a change in mutual capacitance between the first electrode group EG1 and the second electrode group EG2. One group among the first electrode group EG1 and the second electrode group EG2 may receive a driving signal, and the other group thereof may output an amount of change in capacitance between the first electrode group EG1 and the second electrode group EG2 as a sensing signal. However, this is merely an example, and a method for driving the input sensor ISP provided in the display device DD of the invention is not limited thereto.

The first electrode group EG1 may include first sensing electrodes IE1-1 to IE1-8. The second electrode group EG2 may include second sensing electrodes IE2-1 to IE2-6. FIG. 6 exemplarily illustrates the first electrode group EG1 including eight first sensing electrodes IE1-1 to IE1-8 each extended along the first direction DR1, and the second electrode group EG2 including six second sensing electrodes IE2-1 to IE2-6 each extended along the second direction DR2, but the number of sensing electrodes is not limited thereto.

Each of the first sensing electrodes IE1-1 to IE1-8 may be extended along the first direction DR1. Each of the first sensing electrodes IE1-1 to IE1-8 may constitute one row parallel to the first direction DR1. The first sensing electrodes IE1-1 to IE1-8 may be arranged adjacent to each other along the second direction DR2.

Each of the first sensing electrodes IE1-1 to IE1-8 may include first sensors SP1 and first connectors CP1. The first sensors SP1 constituting one first sensing electrode may be arranged along the first direction DR1. Each of the first connectors CP1 may connect two first sensors SP1 adjacent in the first direction DR1 among the first sensors SP1 to each other. The first sensors SP1 and the first connectors CP1 may be disposed on different layers and connected to each other. For example, the first sensors SP1 may be disposed on the first sensing insulating layer IS-IL1 and included in the first conductive layer IS-CL1, and the first connectors CP1 may be disposed on the second sensing insulating layer IS-IL2 and included in the second conductive layer IS-CL2.

Each of the second sensing electrodes IE2-1 to IE2-6 may be extended along the second direction DR2. Each of the second sensing electrodes IE2-1 to IE2-6 may constitute one column parallel to the second direction DR2. The second sensing electrodes IE2-1 to IE2-6 may be arranged adjacent to each other along the first direction DR1.

Each of the second sensing electrodes IE2-1 to IE2-6 may include second sensors SP2 and second connectors CP2. The second sensors SP2 constituting one second sensing electrode may be arranged along the second direction DR2. Each of the second connectors CP2 may connect two second sensors SP2 adjacent in the second direction DR2 among the second sensors SP2 to each other. The second sensors SP2 and the second connectors CP2 may be disposed on the same layer as each other and have an integral shape (e.g., a single body). For example, the second sensors SP2 and the second connectors CP2 may be disposed on the first sensing insulating layer IS-IL1 and included in the first conductive layer IS-CL1. That is, the first connectors CP1 and the second connectors CP2 may intersect each other on a plane while being electrically insulated from each other.

Meanwhile, the length or area occupied by the first sensing electrodes IE1-1 to IE1-8 and the second sensing electrodes IE2-1 to IE2-6 may vary depending on the arrangement of the sensing electrodes, the planar area of the sensing region I-AA, and the like.

Each of the first sensors SP1, the second sensors SP2, the first connectors CP1, and the second connectors CP2 may have conductivity (e.g., electrical conductivity). Each of the first sensors SP1, the second sensors SP2, the first connectors CP1, and the second connectors CP2 may be formed from or include the first conductive layer IS-CL1 or the second conductive layer IS-CL2 described above.

In FIG. 6, each of the first sensors SP1 and the second sensors SP2 is illustrated in a rhombic shape. However, this is exemplarily illustrated, and each of the first sensors SP1 and the second sensors SP2 may have various planar shapes. In addition, in FIG. 6, each of the first connectors CP1 is illustrated in a straight line shape. However, this is exemplarily illustrated, and each of the first connectors CP1 may be deformed into a curved line shape of “A” and/or “V” so as not to overlap the second connectors CP2.

The first sensing electrodes IE1-1 to IE1-8 and the second sensing electrodes IE2-1 to IE2-6 may overlap the display region DA (see FIG. 5) of the display panel DP (see FIG. 5) on a plane. Accordingly, each of the first sensing electrodes IE1-1 to IE1-8 and the second sensing electrodes IE2-1 to IE2-6 may include an optically clear electrically conductive material. Alternatively, the embodiment of the invention is not limited thereto, and each of the first sensing electrodes IE1-1 to IE1-8 and the second sensing electrodes IE2-1 to IE2-6 may include a mesh pattern (e.g., solid material portions spaced apart from each other by openings in the solid material). The first sensing electrodes IE1-1 to IE1-8 and the second sensing electrodes IE2-1 to IE2-6 may be provided in various manners to an extent in which the visibility of an image IM provided from the display panel DP is not degraded, and are not limited to any one embodiment.

The first sensing signal line group SG1 may include the same number of first sensing signal lines as the first sensing electrodes IE1-1 to IE1-8 (e.g., in one-to-one correspondence). The first sensing signal lines may be connected to one end among opposing ends of the first sensing electrodes IE1-1 to IE11-8. For example, the first sensing signal line group SG1 may be divided into two groups defined as a first signal line group SG1-1 on one side and a first signal line group SG1-2 on the other side.

The first signal line group SG1-1 on one side may be connected to the left side (e.g., a first end) of some sensing electrodes among the first sensing electrodes IE1-1 to IE11-8. The first signal line group SG1-2 on the other side may be connected to the right side (e.g., a second end opposite to the first end) of the remaining sensing electrodes among the first sensing electrodes IE1-1 to IE11-8, which are not connected to the first signal line group SG1-1 on one side. The first signal line group SG1-1 on one side and the first signal line group SG1-2 on the other side may be spaced apart from each other in the first direction DR1 on a plane with the sensing region I-AA interposed therebetween. Since the first sensing signal lines of the first sensing signal line group SG1 are divided into both sides and disposed, the area of the line region I-NAA may be reduced.

Specifically, the first signal line group SG1-1 on one side may be electrically connected to sensing electrodes constituting an odd-numbered row among the first sensing electrodes IE1-1 to IE11-8, and the first signal line group SG1-2 on the other side may be electrically connected to sensing electrodes constituting an even-numbered row among the first sensing electrodes IE1-1 to IE11-8.

However, the arrangement of the first sensing signal lines of the first sensing signal line group SG1 is not limited to the illustrated embodiment. For example, the first sensing signal lines may be connected to both of the opposing ends of the first sensing electrodes IE1-1 to IE11-8. Alternatively, the first sensing signal line group SG1 may not be divided into two groups, and instead, may all be connected to the left side of the first sensing electrodes IE1-1 to IE1-8, or may all be connected to the right side of the first sensing electrodes IE1-1 to IE1-8.

The second sensing signal line group SG2 may include the same number of second sensing signal lines as the second sensing electrodes IE2-1 to IE2-6. The first sensing signal lines may be connected to one end among opposing ends of the second sensing electrodes IE2-1 to IE2-6. Referring to FIG. 6, the second sensing signal lines of the second sensing signal line group SG2 may respectively be connected to lower ends of the second sensing electrodes IE2-1 to IE2-6.

The input sensor ISP may include a sensing pad PD-I provided in plural, The sensing signal lines of the first sensing signal line group SG1 and the second sensing signal line group SG2 may respectively be connected to corresponding sensing pads PD-I among the sensing pads PD-I arranged along the first direction DR1. The sensing pad PD-I may be connected to the same circuit board which is connected to the display panel DP, or without being limited thereto, may be connected to a circuit board separate from the circuit board connected to the display panel DP and independently controlled, but the embodiment of the invention is not limited thereto.

The sensing pad PD-I may be formed on (or in) a different layer from a pad PD of the display panel DP. However, the embodiment of the invention is not limited thereto, and the sensing pad PD-I may be formed on the same layer as the pad PD of the display panel DP, and ends of the sensing signal lines of the input sensor ISP may be electrically connected to corresponding sensing pads PD-I through contact holes, respectively.

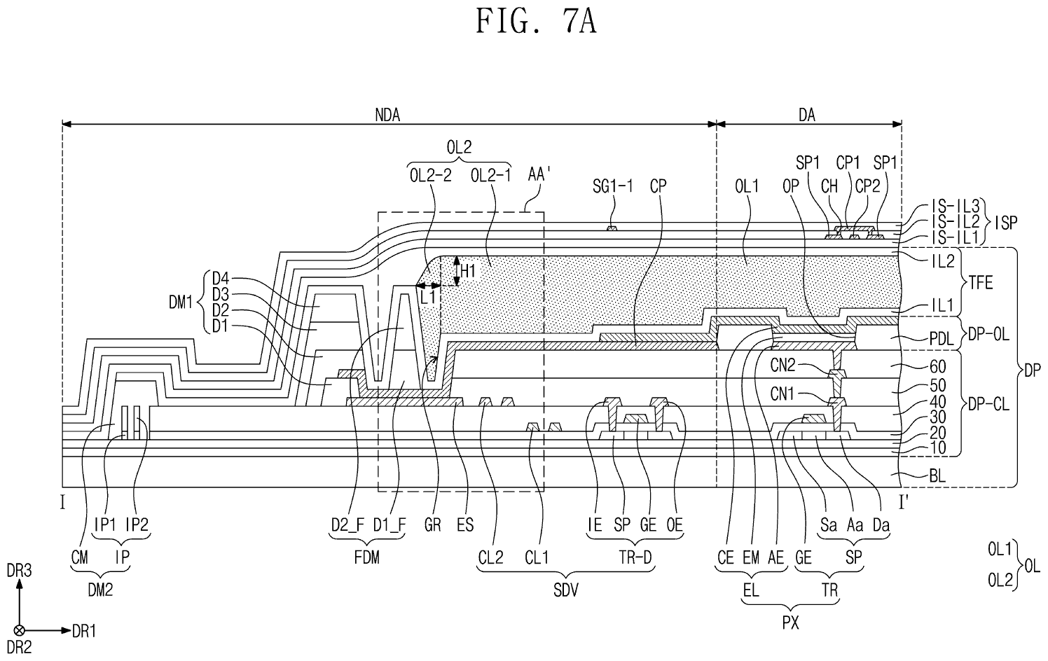

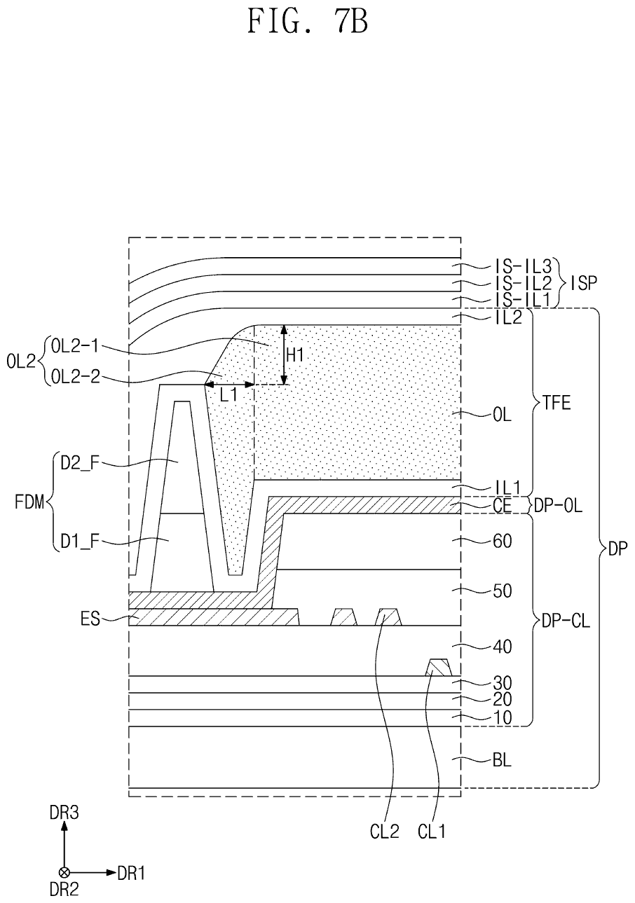

FIG. 7A is a cross-sectional view of a portion corresponding to line I-I′ illustrated in FIG. 5. FIG. 7B is an enlarged cross-sectional view of a first region AA′ illustrated in FIG. 7A.

Illustratively, FIG. 7A illustrates a cross-section of the display panel DP and the input sensor ISP each corresponding to the display region DA and the non-display region NDA which is adjacent to the display region DA.

Among components illustrated in FIG. 7A and FIG. 7B, the same components as those described with reference to the above-described drawings will not be described or briefly described.

Referring to FIG. 7A, the display panel DP may include the base layer BL, the circuit layer DP-CL, the display element layer DP-OL, the encapsulation layer TFE, and a dam provide in plural including a flow control dam FDM, a first dam DM1 and a second dam DM2.

The base layer BL may include a glass substrate, a metal substrate, a polymer substrate, or an inorganic composite substrate. In an embodiment, the base layer BL may include a synthetic resin layer. For example, the synthetic resin layer may include at least one of an acrylic resin, a methacrylic resin, a polyisoprene-based resin, a vinyl-based resin, an epoxy-based resin, a urethane-based resin, a cellulose-based resin, a siloxane-based resin, a polyamide-based resin, a perylene-based resin and a polyimide-based resin. However, materials of the base layer BL are not limited to the above-described examples.

The circuit layer DP-CL may be disposed on the base layer BL. The circuit layer DP-CL may include at least one insulating layer, a conductive pattern, and a semiconductor pattern. In a manufacturing process of the display panel DP, an insulating layer, a semiconductor layer, and a conductive layer may be formed on the base layer BL by a method, such as coating, deposition, or the like. Thereafter, the insulating layer, the semiconductor layer, and the conductive layer may be selectively patterned by a photolithography method. Through the above-described process, a semiconductor pattern, a conductive pattern, a signal line, and the like included in the circuit layer DP-CL may be formed.

In FIG. 7A, first to sixth insulating layers 10, 20, 30, 40, 50, and 60, the semiconductor pattern, and the conductive pattern included in the circuit layer DP-CL are illustrated. However, a cross-section of the circuit layer DP-CL illustrated in FIG. 7A is merely an example, and a stacked structure of the circuit layer DP-CL may be variously modified according to a process operation, a process method, or a configuration of elements included in a pixel.

The first insulating layer 10 may be disposed on the base layer BL. The first insulating layer 10 may include an inorganic layer and may be provided as a barrier layer on the base layer BL. The first insulating layer 10 provided as the barrier layer may prevent foreign substances from being introduced from the outside. The first insulating layer 10 may include at least one of a silicon oxide layer and a silicon nitride layer. In an embodiment, the first insulating layer 10 provided as the barrier layer may include silicon oxide layers and silicon nitride layers which are alternately stacked.

The second insulating layer 20 may be disposed on the first insulating layer 10. The second insulating layer 20 may include an inorganic layer and may be provided as a buffer layer on the base layer BL. The second insulating layer 20 provided as the buffer layer may improve coupling force between the base layer BL and the semiconductor pattern or the conductive pattern. The second insulating layer 20 may include at least one of a silicon oxide layer and a silicon nitride layer. In an embodiment, the second insulating layer 20 provided as the buffer layer may include silicon oxide layers and silicon nitride layers which are alternately stacked.

The active elements of the pixels PX may be disposed on the second insulating layer 20. Each of the pixels PX may have an equivalent circuit including a transistor TR, at least one capacitor, and a light emitting element EL, and an equivalent circuit diagram of the pixel PX may be modified in various forms. A semiconductor pattern SP to be described later may be arranged by a predetermined rule across the pixels PX according to an equivalent circuit diagram. FIG. 7A exemplarily illustrates a partial configuration of one pixel PX.

The transistor TR may include the semiconductor pattern SP and a gate GE. The semiconductor pattern SP may be disposed on the second insulating layer 20. The semiconductor pattern SP may include a silicon semiconductor, and may include a single crystal silicon semiconductor, a polysilicon semiconductor, or an amorphous silicon semiconductor. Also, the semiconductor pattern SP may include an oxide semiconductor. The semiconductor pattern SP of a semiconductor layer according to an embodiment of the invention may be formed of various materials as long as they have semiconductor properties, and is not limited to any one embodiment.

A source Sa, a drain Da, and a channel Aa of the transistor TR may be formed from or defined by the semiconductor pattern SP of the transistor TR. The semiconductor pattern SP may be divided into a plurality of regions according to electrical conductivity. For example, electrical properties of the semiconductor pattern SP may vary depending on whether the semiconductor pattern SP is doped or whether a metal oxide is reduced. A region in which a metal oxide is reduced (hereinafter, a reduction region) may have higher conductivity than a region in which the metal oxide is not reduced (hereinafter, a non-reduction region). In the semiconductor pattern, a region with high conductivity may serve as an electrode or a signal line, and may correspond to the source Sa and the drain Da of the transistor TR. A region non-doped or not-reduced, thereby having relatively low conductivity, may correspond to the channel Aa (or active) of the transistor TR.

In an embodiment, the semiconductor pattern SP may include a first region having high conductivity and a second region having low conductivity. The first region may be doped with an N-type dopant or a P-type dopant. A P-type transistor may include a doped region which has been doped with the P-type dopant, and an N-type transistor may include a doped region which has been doped with the N-type dopant. The second region may be a non-doped region, or a region doped to a concentration lower than that of the first region.

The third to sixth insulating layers 30, 40, 50, and 60 may be stacked on the semiconductor pattern SP. The third to sixth insulating layers 30, 40, 50, and 60 may include an inorganic layer or an organic layer. For example, the inorganic layer may include at least one of aluminum oxide, titanium oxide, silicon oxide, silicon nitride, silicon oxynitride, zirconium oxide and hafnium oxide. The organic layer may include a phenolic polymer, an acrylic polymer, an imide-based polymer, an aryl ether-based polymer, an amide-based polymer, a fluorine-based polymer, a p-xylene-based polymer, a vinyl alcohol-based polymer, and a polymer in combination thereof. However, materials of an insulating layer are not limited to the above-described examples.

The third insulating layer 30 may be disposed on the second insulating layer 20 and cover the semiconductor pattern SP. The third insulating layer 30 may be disposed between the semiconductor pattern SP of the transistor TR and the gate GE. In an embodiment, the third insulating layer 30 may be an inorganic layer having a single-layered or multi-layered structure.

The gate GE may be disposed on the third insulating layer 30. The gate GE may be a portion of the conductive pattern of the circuit layer DP-CL. On a plane, the gate GE may overlap the channel Aa of the transistor TR. In a process of doping the semiconductor pattern SP, the gate GE may function as a mask.

Meanwhile, the transistor TR of FIG. 7A is exemplarily illustrated, and the source Sa or the drain Da may be electrodes independently formed from the semiconductor pattern SP. In this case, the source Sa and the drain Da may be in contact with the semiconductor pattern SP, or may be connected to the semiconductor pattern SP through a via defined in an insulating layer therebetween. In addition, in an embodiment, the gate GE may be disposed on a lower side of the semiconductor pattern SP. The transistor TR according to an embodiment of the invention may be formed in various structures, and is not limited to any one embodiment.

The fourth insulating layer 40 may be disposed on the third insulating layer 30 and cover the gate GE. In an embodiment, the fourth insulating layer 40 may be an inorganic layer having a single-layered or multi-layered structure. The fifth insulating layer 50 may be disposed on the fourth insulating layer 40. In an embodiment, the fifth insulating layer 50 may be an organic layer having a single-layered or multi-layered structure.

A first connection electrode CN1 may be disposed on the fourth insulating layer 40. A second connection electrode CN2 may be disposed on the fifth insulating layer 50. The first connection electrode CN1 may be electrically connected to the semiconductor pattern SP through a contact-hole passing through a total thickness of the third insulating layer 30 and the fourth insulating layer 40. The second connection electrode CN2 may be electrically connected to the first connection electrode CN1 through a contact-hole passing through a thickness of the fifth insulating layer 50. The sixth insulating layer 60 may be disposed on the fifth insulating layer 50 and cover the second connection electrode CN2.

Meanwhile, at least one of the first connection electrode CN1 and the second connection electrode CN2 may be omitted. Alternatively, an additional connection electrode which connects the light emitting element EL and the transistor TR to each other may be further disposed. The electrical connection between the light emitting element EL and the transistor TR may be variously changed depending on the number of insulating layers disposed between the light emitting element EL and the transistor TR, but the embodiment of the invention is not limited to any one embodiment.

The circuit layer DP-CL may include a scan driver SDV disposed on the base layer BL. FIG. 7A schematically illustrates a cross-section of the scan driver SDV disposed on the non-display region NDA as an example, but the embodiment of the invention is not limited thereto. In an embodiment, at least a partial configuration of the scan driver SDV may be disposed in the display region DA and overlap the light emitting element EL.

The scan driver SDV may include a driving transistor TR-D, first signal lines CL1, and second signal lines CL2. The active elements of the driving transistor TR-D may be disposed on the second insulating layer 20. Various patterns and layers of the driving transistor TR-D may be formed on the same layer as the transistor TR of the pixel PX. However, the embodiment of the invention is not limited thereto, and the driving transistor TR-D may be disposed on a different layer from the transistor TR of the pixel PX. As being in a same layer, elements may be formed in a same process and/or include a same material as each other, elements may be respective portions of a same material layer, elements may be on a same layer by forming an interface with a same underlying or overlying layer, elements may be coplanar with each other or be disposed in a same thickness of a stacked structure, etc., without being limited thereto.

The driving transistor TR-D may include a semiconductor pattern SP, a gate GE, a source IE, and a drain OE. Each of the gate GE, the source IE, and the drain OE may be formed as an electrode and be independently formed from the semiconductor pattern SP, such as being in a different layer. The source IE and the drain OE may be disposed on the fourth insulating layer 40 and be connected to the semiconductor pattern SP through a contact-hole passing through a total thickness of the third insulating layer 30 and the fourth insulating layer 40.

Meanwhile, this is exemplarily illustrated, and the driving transistor TR-D may be formed in the same structure as the transistor TR of the pixel PX. At this time, the driving transistor TR-D may be formed through the same process as the transistor TR of the pixel PX, so that the process may be simplified and the process cost may be reduced.

The first signal lines CL1 and the second signal lines CL2 may be disposed on different layers from each other. In an embodiment, the first signal lines CL1 may be disposed on the same layer as the gate GE of the driving transistor TR-D, and the second signal lines CL2 may be disposed on the same layer as the source IE or the drain OE. The first signal lines CL1 and the second signal lines CL2 electrically connect the driving transistor TR-D and other components of the scan driver SDV, to each other along the scan driver SDV, which are not illustrated. Meanwhile, this is exemplarily illustrated, and either the first signal lines CL1 or the second signal lines CL2 may be omitted.

The display element layer DP-OL may be disposed on the circuit layer DP-CL. The display element layer DP-OL may include the light emitting element EL and a pixel defining film PDL. The light emitting element EL may be electrically connected to the transistor TR and constitute active elements of the pixel PX together with the transistor TR among all the layers within the stacked structure of the pixel PX.

The light emitting element EL may be disposed on the display region DA and emit light. For example, the light emitting element EL may include an organic light emitting element, a quantum dot light emitting element, a micro LED light emitting element, or a nano LED light emitting element. However, the embodiment of the invention is not limited thereto, and the light emitting element EL may include various embodiments as long as light can be generated or the amount of light can be controlled in response to an electrical signal.

The light emitting element EL may include a first electrode AE, a light emitting layer EM, and a second electrode CE. The first electrode AE may be disposed on the sixth insulating layer 60. The first electrode AE may be connected to the second connection electrode CN2 through a contact-hole passing through a thickness of the sixth insulating layer 60.

The pixel defining film PDL as a solid portion of a pixel defining layer may be disposed on the first electrode AE and the sixth insulating layer 60, and may expose at least a portion of the first electrode AE to outside the pixel defining layer. An emission opening OP which exposes at least a portion of the first electrode AE to outside the pixel defining film PDL may be defined in the pixel defining film PDL. Here, the emission opening together with a solid material of the pixel defining film PDL may define the pixel defining layer.

The pixel defining film PDL may be formed of (or include) a polymer resin. For example, the pixel defining film PDL may include a polyacrylate-based resin or polyimide-based resin. The pixel defining film PDL may further include an inorganic material in addition to the polymer resin. In addition, the pixel defining film PDL may be formed of an inorganic material. For example, the pixel defining film PDL may be formed by including silicon nitride (SiNₓ), silicon oxide (SiOₓ), silicon oxide (SiOₓN_{y}), or the like.

Meanwhile, in an embodiment, the pixel defining film PDL may include a light absorbing material. The pixel defining film PDL may include a black coloring agent. The black coloring agent may include a black dye and a black pigment. The black coloring agent may include carbon black, a metal such as chromium, or an oxide thereof.

The light emitting layer EM may be disposed on the first electrode AE. The light emitting layer EM may be disposed corresponding to the emission opening OP of the pixel defining film PDL. The light emitting layer EM may provide a predetermined colored light. The light emitting layer EM may include an organic light emitting material and/or an inorganic light emitting material. For example, the light emitting layer EM may include a fluorescent or phosphorescent material, an organometallic complex light emitting material, or a quantum dot.

The second electrode CE may be disposed on the light emitting layer EM. The second electrode CE may be commonly disposed across the pixels PX. The second electrode CE may be provided with a common voltage, and the second electrode CE may be referred as a common electrode.

Meanwhile, the light emitting element EL may further include emission control layers (not shown) disposed between the first electrode AE and the second electrode CE. For example, the light emitting element EL may include a hole transport layer or a hole injection layer disposed between the first electrode AE and the light emitting layer EM, and may include an electron transport layer or an electron injection layer disposed between the light emitting layer EM and the second electrode CE.

A first voltage may be applied to the first electrode AE through the transistor TR, and a common voltage may be applied to the second electrode CE. A hole and an electron injected into the light emitting layer EM may be combined to form an exciton, and when the exciton transits to a ground state, the light emitting element EL may emit light through the display region DA.

The display panel DP may include a power pattern ES and a conductive pattern CP each electrically connected to the second electrode CE. The power pattern ES may be disposed in the non-display region NDA, and the conductive pattern CP may be disposed on the power pattern ES. The conductive pattern CP may be extended further from the power pattern ES in a direction along the base layer BL and toward the display region DA. The conductive pattern CP may electrically connect the power pattern ES to the second electrode CE, and the power pattern ES may provide a power voltage to the second electrode CE via the conductive pattern CP.

Referring to FIG. 7A and FIG. 7B, the encapsulation layer TFE may be disposed on the display element layer DP-OL and cover the light emitting element EL. That is, the encapsulation layer TFE may seal the light emitting element EL. The encapsulation layer TFE may include at least one insulating film, and the insulating film may be provided as an inorganic film or an organic film. In an embodiment, the encapsulation layer TFE may include a plurality of insulating films, at least one of the plurality of insulating films may be provided as an organic film, and at least one thereof may be provided as an inorganic film. FIG. 7A illustrates the encapsulation layer TFE including a first inorganic film IL1, an organic film OL, and a second inorganic film IL2.

The first inorganic film IL1 may be disposed on the second electrode CE. The first inorganic film IL1 as an inorganic encapsulation film may extend from the display region DA to cover the flow control dam FDM, the first dam DM1, and the second dam DM2 which are in the non-display region NDA, which will be described later. The first inorganic film IL1 may define a recess GR in a region between the flow control dam FDM and an end (side) surface of the fifth insulating layer 50 and between the flow control dam FDM and an end (side) surface of the sixth insulating layer 60.

In the display region DA and the non-display region NDA, the organic film OL may be disposed on the first inorganic film IL1. Hereinafter, a material portion of the organic film OL which is disposed in the display region DA may be defined as a first organic film OL1, and a material portion of the organic film OL which is disposed in the non-display region NDA may be defined as a second organic film OL2.

An upper surface of the first organic film OL1 which is furthest from the display element layer DP-OL may be flat. An upper surface of a portion of the second organic film OL2 may be flat. An upper surface of another portion of the second organic film OL2 which is further from the display region DA than the portion may have an inclination (e.g., be inclined). The outermost side of the second organic film OL2 which is furthest from the display region DA may have the inclination. Hereinafter, the portion of the second organic film OL2 having a flat upper surface may be defined as a 2-1 organic film OL2-1 (e.g., a first-second organic film), and the portion of the second organic film OL2 having an inclined upper surface may be defined as a 2-2 organic film OL2-2 (e.g., a second-second organic film).

On a plane, the 2-2 organic film OL2-2 may be extend into the recess GR from outside thereof to be disposed in the recess GR. The upper surface of the 2-2 organic film OL2-2 may be extended from one side of the flow control dam FDM to the upper surface of the 2-1 organic film OL2-1 in an inclined direction. At a boundary between the upper surface of the 2-1 organic film OL2-1 and the upper surface of the 2-2 organic film OL2-2, the height of the upper surface of the 2-1 organic film OL2-1 and the height of the upper surface of the 2-2 organic film OL2-2 may be the same.

The slope of the 2-2 organic film OL2-2 may be defined as a first height H1 with respect to a first length L1. The first length L1 may be defined as a length in the first direction DR1 of a portion of the 2-2 organic film OL2-2 disposed above the upper surface of the flow control dam FDM. The first height H1 may be defined, at a boundary between the 2-1 organic film OL2-1 and the 2-2 organic film OL2-2, as a length in the third direction DR3 of the 2-2 organic film OL2-2 disposed above the upper surface of the flow control dam FDM. The slope of the upper surface of the 2-2 organic film OL2-2 may be inversely proportional to the first length L1. The slope of the upper surface of the 2-2 organic film OL2-2 may be proportional to the first height H1.

The organic film OL as an organic encapsulation film formed with the organic material layer may protect the light emitting element EL from foreign substances such as dust particles. For example, the organic film OL may include an acrylic resin, but a material of the organic film OL is not limited thereto. In addition, at a boundary between the non-display region NDA and the display region DA, the organic film OL having a dielectric constant may reduce noise generated between the circuit layer DP-CL and the input sensor ISP.

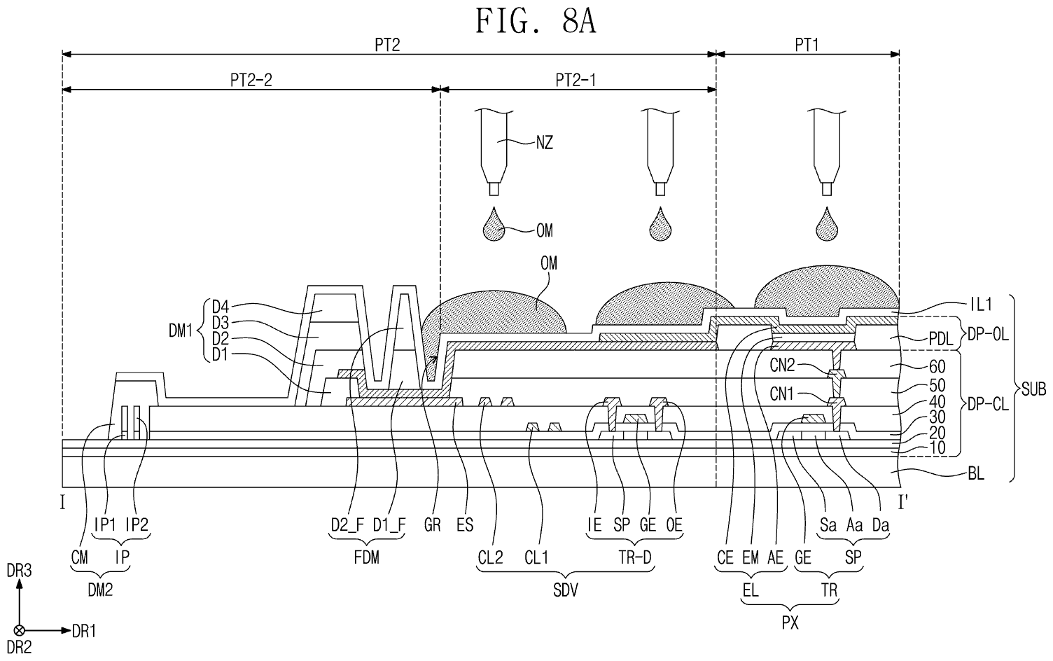

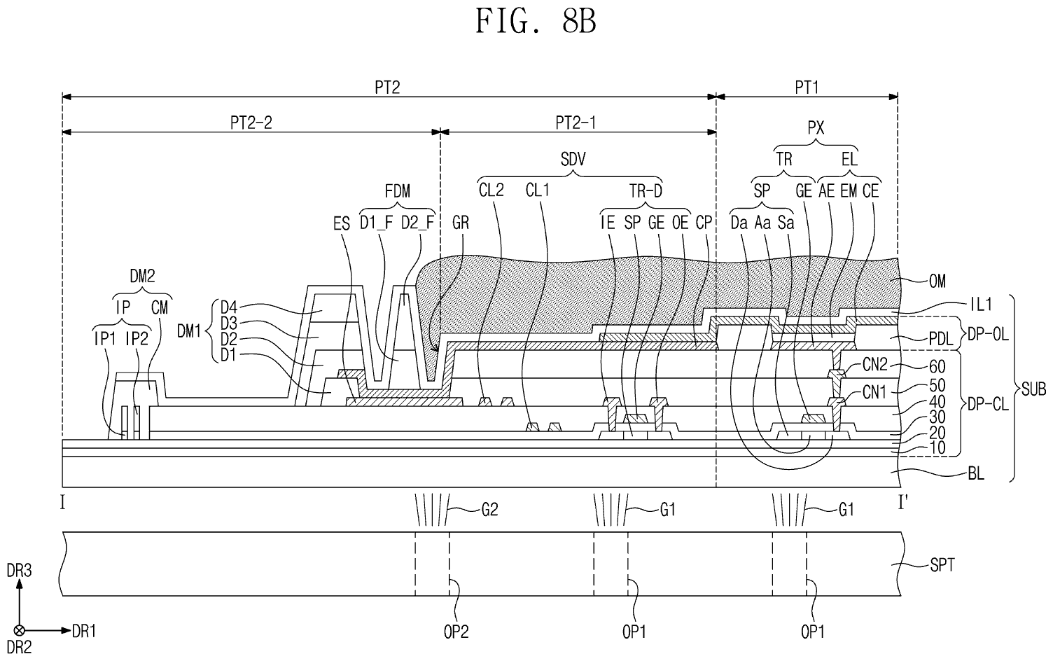

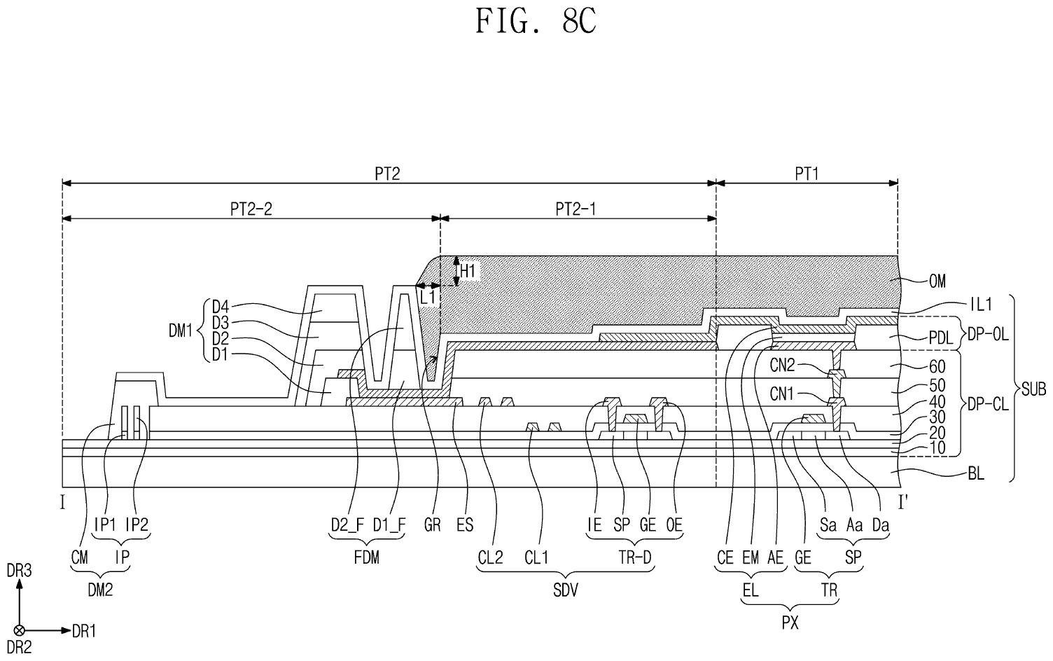

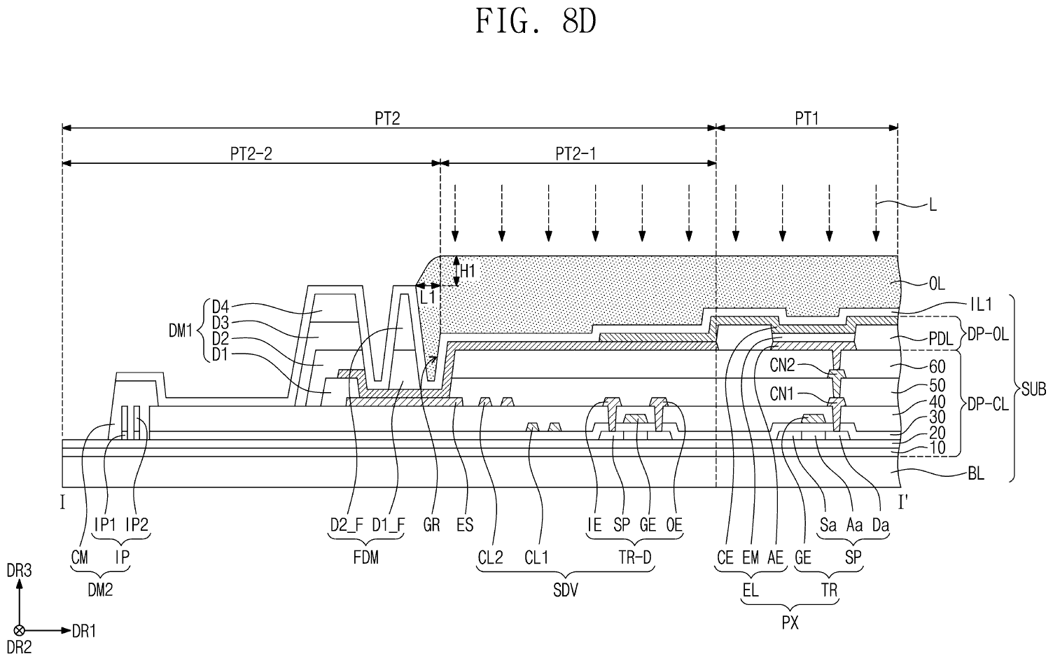

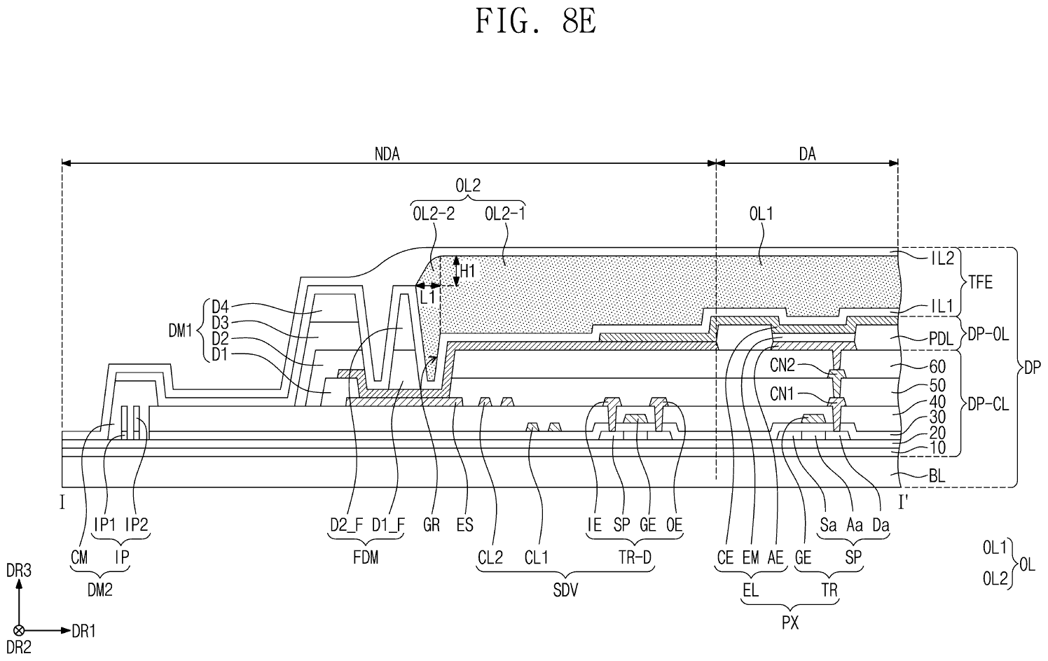

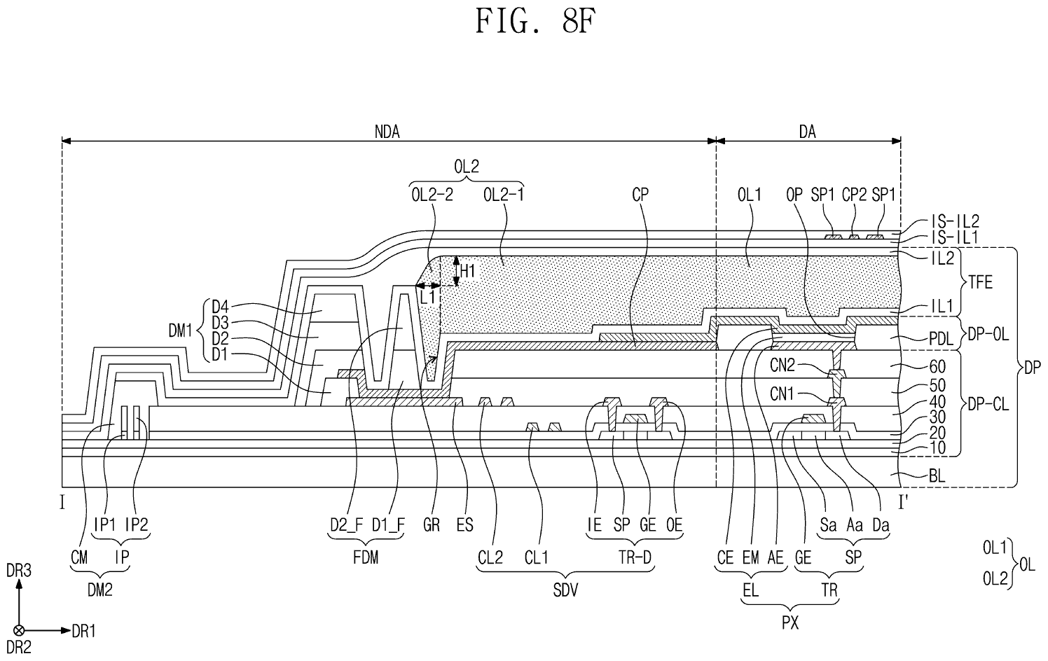

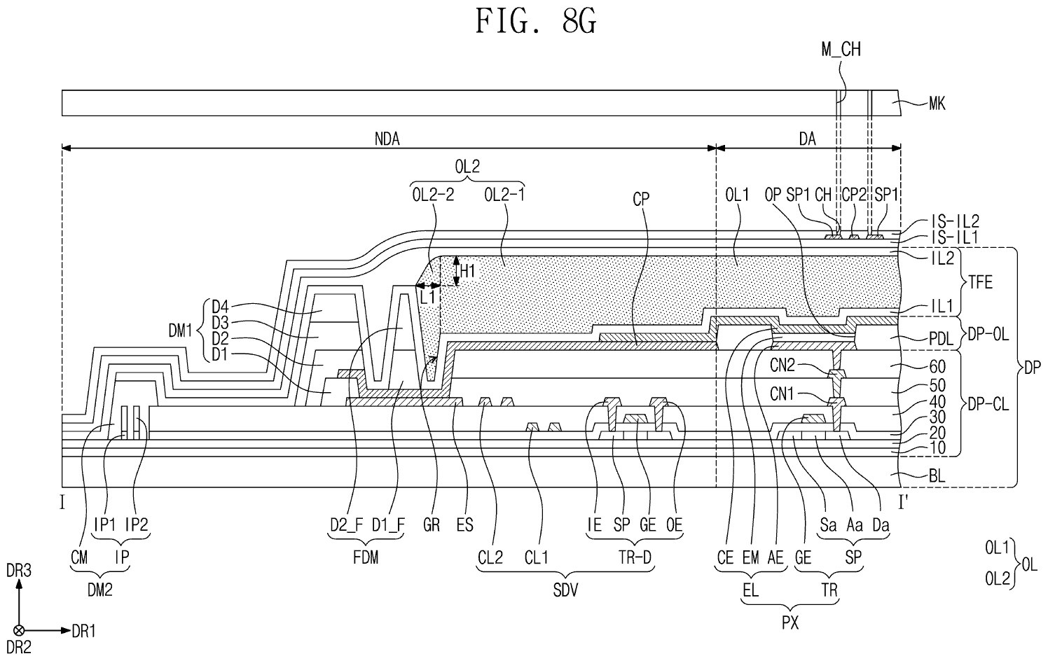

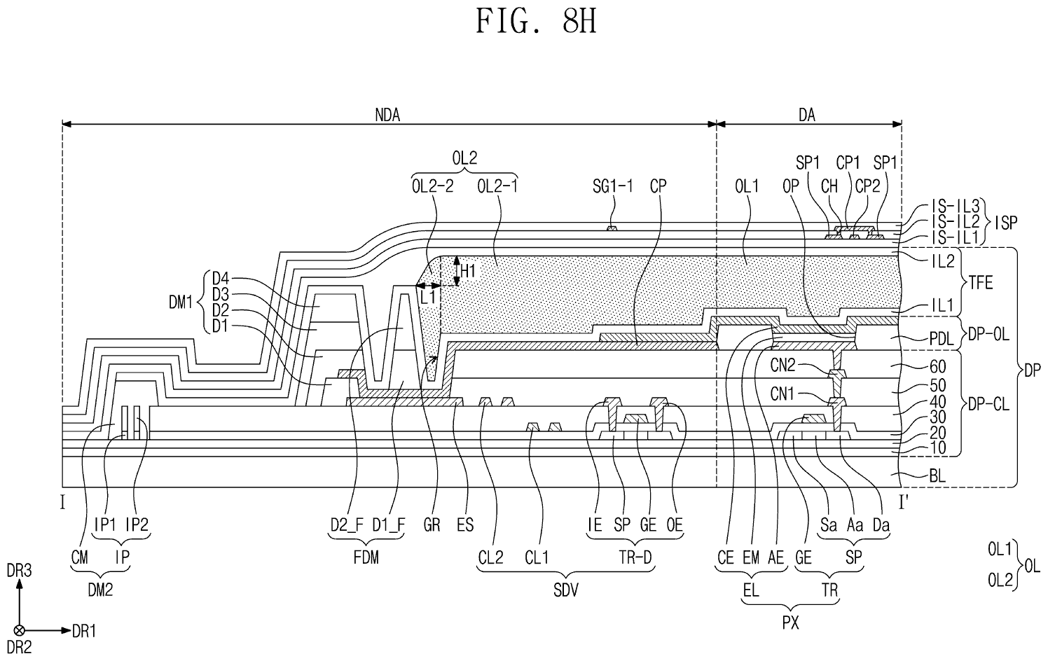

The organic film OL may be formed by an inkjet printing method. The formation of the organic film OL may be described in detail with reference to FIG. 8A to FIG. 8E.

The second inorganic film IL2 as an inorganic encapsulation film may be disposed on the organic film OL and cover the organic film OL. The first inorganic film IL1 and the second inorganic film IL2 may protect the light emitting element EL from moisture and/or oxygen. For example, the first inorganic film IL1 and the second inorganic film IL2 may include at least one of aluminum oxide, titanium oxide, silicon oxide, silicon nitride, silicon oxynitride, zirconium oxide and hafnium oxide, but materials thereof are not limited thereto. The first inorganic film IL1 and the second inorganic film IL2 may be extended from the display region DA and into the non-display region NDA to be disposed on the non-display region NDA. The first inorganic film IL1 may cover the power pattern ES and the conductive pattern CP, and the second inorganic film IL2 may contact the first inorganic film IL1 in the non-display region NDA. As being in contact, elements may form an interface therebetween.

Referring to FIG. 6 and FIG. 7A, the first conductive layer IS-CL1 (see FIG. 4) and the second conductive layer IS-CL2 (see FIG. 4) of the input sensor ISP may include sensing electrodes or sensing signal lines as illustrated in FIG. 6. Hereinafter, FIG. 7A schematically illustrates the components of the input sensor ISP as an example, and the following description is based thereon, but the arrangement of the components of the input sensor ISP is not limited to what is illustrated.

The first sensors SP1 and the second connectors CP2 may be formed from the first conductive layer IS-CL1 and be disposed on the first sensing insulating layer IS-IL1. Also, although not illustrated in FIG. 7A, the second sensors SP2 (see FIG. 6) may be disposed on the second sensing insulating layer IS-IL2. The first sensors SP1, the second sensors SP2 (see FIG. 6), and the second connectors CP2 may be disposed overlapping the display region DA. The second sensing insulating layer IS-IL2 may be disposed on the first sensing insulating layer IS-IL1 and cover the first sensors SP1, the second sensors SP2 (see FIG. 6), and the second connectors CP2. The second sensing insulating layer IS-IL2 may be extended from the display region DA and be also disposed on the non-display region NDA.

The first connectors CP1 may be formed from the second conductive layer IS-CL2, and be disposed on the second sensing insulating layer IS-IL2. The first connectors CP1 may be electrically connected to the first sensors SP1 through a contact-hole CH passing through the second sensing insulating layer IS-IL2. The first connectors CP1 may overlap the second connectors CP2 on a plane, and may be electrically insulated from each other by the second sensing insulating layer IS-IL2.

As illustrated in FIG. 6, the sensors SP1 and SP2 of the input sensor ISP, and the connectors CP1 and CP2 may have a mesh-shaped pattern, and be disposed corresponding to a region in which the pixel defining film PDL is disposed. Accordingly, the input sensor ISP may not affect the emission efficiency of the light emitting element EL. However, the embodiment of the invention is not limited thereto, and the input sensor ISP may be a single-shaped pattern overlapping the light-emitting elements EL, or may include a conductive clear material.

A portion of the second conductive layer IS-CL2 (see FIG. 4) may form sensing signal lines. FIG. 7A exemplarily illustrates some of the sensing signal lines of the first signal line group SG1-1 described above. The sensing signal lines may be disposed on the second sensing insulating layer IS-IL2. However, the embodiment of the invention is not limited thereto, and the sensing signal lines may be part of the first conductive layer IS-CL1. The sensing signal lines may be disposed in the non-display region NDA.

The third sensing insulating layer IS-IL3 may be disposed on the second sensing insulating layer IS-IL2 and cover the second connectors CP2 and the sensing signal lines. The third sensing insulating layer IS-IL3 may be extended from the display region DA and be also disposed on the non-display region NDA.

The conductive pattern CP may be disposed between the sensing signal lines and the scan driver SDV, and may overlap each of the sensing signal lines and the scan driver SDV. The conductive pattern CP may serve as a shielding electrode. That is, the conductive pattern CP may prevent the occurrence of parasitic capacitance between the sensing signal lines and the scan driver SDV. Accordingly, a signal transmitted to the sensing signal lines may be changed by the scan driver SDV and reduce a shape in which noise is generated.

Referring to FIG. 7A, a plurality of dams including the flow control dam FDM, the first dam DM1, and the second dam DM2 may be disposed in the non-display region NDA. The flow control dam FDM may be disposed on an outer side of an end surface of the organic film OL which is furthest from the display region DA. The organic film OL may be disposed on one side among opposing sides of the flow control dam FDM which are opposite to each other in the first direction DR1. The one side of both sides of the flow control dam FDM opposite to each other in the first direction DR1 may be defined as a side adjacent to the display region DA (e.g., a side which is closest to the display region DA). The flow control dam FDM may control a flow of an organic material of the organic film OL toward an outer edge of the base layer BL which is furthest from the display region DA. The flow control dam FDM may be covered by the first inorganic film IL1.

Although FIG. 7A exemplarily illustrates the flow control dam FDM disposed on the power pattern ES, the embodiment of the invention is not limited thereto, and the flow control dam FDM may be disposed closer to an outer side of the non-display region NDA (e.g., closer to an outer edge of the base layer BL) than the power pattern ES, or may not overlap the power pattern ES. That is, the position of the flow control dam FDM is not limited to any one position as long as the flow control dam FDM can control the flow of the organic material of the organic film OL.

The flow control dam FDM may have a multi-layered structure. For example, the flow control dam FDM may include a first layer D1_F and a second layer D2_F. At least some of the layers D1_F and D2_F included in the flow control dam FDM may simultaneously be formed during a process of forming the insulating layers 10, 20, 30, 40, 50, and 60 of the circuit layer DP-CL, or the pixel defining film PDL. For example, the first layer D1_F may be formed by the same process as the sixth insulating layer 60, and the second layer D2_F may be formed by the same process as the pixel defining film PDL. However, this is merely an example, and the flow control dam FDM may have a single-layered structure or more multi-layered structure than illustrated, and is not limited to any one embodiment. That is, a respective thickness portion of the flow control dam FDM may be a respective portion of a material layer forming a layer among the insulating layers 10, 20, 30, 40, 50, and 60 of the circuit layer DP-CL and/or the pixel defining film PDL.

The first dam DM1 may be disposed on an outer side of the flow control dam FDM and spaced apart from the flow control dam FDM. The first dam DM1 may be spaced apart from the flow control dam FDM in a direction (e.g., the opposite direction to the first direction DR1) away from the display region DA from a boundary between the display region DA and the non-display region NDA. The first dam DM1 may be covered by a first inorganic film IL1. Although FIG. 7A exemplarily illustrates the first dam DM1 overlapping a portion of the power pattern ES, the embodiment of the invention is not limited thereto, and the first dam DM1 may be disposed closer to the outer side of the non-display region NDA than the power pattern ES, or may not overlap the power pattern ES. That is, the position of the first dam DM1 is not limited to any one position.

The first dam DM1 may have a multi-layered structure. For example, the first dam DM1 may include thickness portions including a first layer D1 formed by the same process as the fifth insulating layer 50, a second layer D2 formed by the same process as the sixth insulating layer 60, a third layer D3 formed by the same process as the pixel defining film PDL, and a fourth layer D4 by a separate process. However, this is merely an example, and the embodiment of the invention is not limited to the above-described example, and at least a portion of the first dam DM1 may be formed simultaneously with any one of the insulating layers 10, 20, 30, 40, 50, and 60 of the circuit layer DP-CL, or the pixel defining film PDL. In addition, the first dam DM1 may have a single-layered structure or more multi-layered structure than illustrated, and is not limited to any one embodiment.

The second dam DM2 may be disposed on an outer side of the first dam DM1. The second dam DM2 may be spaced apart from the first dam DM1 in a direction (e.g., the opposite direction to the first direction DR1) away from the display region DA from a boundary between the display region DA and the non-display region NDA. A portion of the second dam DM2 may be covered by the first inorganic film IL1, and another portion of the second dam DM2 which is exposed outside of the first inorganic film IL1 may be covered by the second inorganic film IL2. However, this is merely an example, and the second dam DM2 may be covered by the second inorganic film IL2. That is, the second dam DM2 is not limited to any one embodiment as long as the second dam DM2 covered by an inorganic film.

The second dam DM2 may mitigate an impact generated at an outer periphery of the display device DD (see FIG. 1) and prevent cracks from being generated in insulating layer. The second dam DM2 may include a plurality of insulating patterns IP and a cover member CM. The plurality of insulating patterns IP may be spaced apart from each other in the first direction DR1, and may be extended lengthwise along the second direction DR2. Between each of the plurality of insulating patterns IP, a separation space or gap may be defined. The cover member CM may cover the front surface of the plurality of insulating patterns IP, and may prevent foreign substances such as a mucosa from being separated from the plurality of insulating patterns IP. The cover member CM may be filled in each space or gap by which the plurality of insulating patterns IP are spaced apart from each other.

Each of the plurality of insulating patterns IP may include a first layer IP1 and a second layer IP2. The first layer IP1 may be disposed on the second insulating layer 20, and the second layer IP2 may be disposed on the first layer IP1. The first layer IP1 may be formed by the same process as the third insulating layer 30, and the second layer IP2 may be formed by the same process as the fourth insulating layer 40.

FIGS. 8A to 8H are cross-sectional views for describing providing of a stacked structure of a display panel DP and an input sensor ISP illustrated in FIG. 7A.

Illustratively, FIG. 8A to FIG. 8H are cross-sectional views of a portion corresponding to line I-I′ illustrated in FIG. 5.

Among components illustrated in FIG. 8A to FIG. 8H, the same components as those described with reference to the above-described drawings will not be described or briefly described.

Referring to FIG. 8A, a preliminary stacked structure of the display panel DP which includes the base layer BL, the circuit layer DP-CL, the display element layer DP-OL, and the first inorganic film IL1 may be defined as a substrate SUB. The substrate SUB may include planar areas such as a first portion PT1 and a second portion PT2 which extends from the first portion PT1 in a direction away from the display region DA. A region in which the light emitting element EL is disposed may be defined as the first portion PT1, and a region in which the light emitting element EL is not disposed may be defined as a second portion PT2. The first portion PT1 may correspond to the display region DA of FIG. 7A, and the second portion PT2 may correspond to the non-display region NDA of FIG. 7A.

An insulating layer such as one or more of the fifth insulating layer 50 and the sixth insulating layer 60 may extend from the display region DA and into the non-display region NDA. The insulating layer may include solid portions spaced apart or disconnected from each other along the first direction DR1. A respective edge or end surface of each of the solid portions may be a side surface which is furthest from the display region DA along the first direction DR1. The insulating layer may define a groove or a plurality of grooves in the non-display region NDA. Referring to FIG. 8A, for example, the flow control dam FDM may be considered within a groove of the insulating layer. The flow control dam FDM may define grooves at opposing sides thereof together with solid portions of the insulating layer.

Within the stacked structure of the substrate SUB, the power pattern ES may be exposed to outside the insulating layer at the groove defined in the insulating layer. The conductive pattern CP may be connected to the power pattern ES within a groove of the insulating layer. The first inorganic film IL1 may extend from the display region DA and into the non-display region NDA to cover the common electrode CE, the conductive pattern CP and the dams, without being limited thereto.

The second portion PT2 may include a 2-1 portion PT2-1 and a 2-2 portion PT2-2. The 2-1 portion PT2-1 may be defined as a region up to an edge or a side surface of the first inorganic film IL1 which is adjacent to the recess GR. The 2-2 portion PT2-2 may be defined as the remaining region of the second portion PT2 other than the 2-1 portion PT2-1.

A method for manufacturing (or providing) a display device DD of the present invention may include providing an organic material OM to the substrate SUB. A plurality of nozzles NZ may be disposed on the substrate SUB. The nozzles NZ may be disposed facing the circuit layer DP-CL and the display element layer DP-OL. The nozzles NZ may provide organic materials OM on the substrate SUB. The organic materials OM may include the same material as the organic film OL illustrated in FIG. 7A. As illustrated in FIG. 8A, the organic materials OM which are initially provided on the substrate SUB may include portions which are spaced apart from each other along the first portion PT1 and the second portion PT2.

Referring to FIG. 8B and FIG. 8C, the method for manufacturing a display device DD of the present invention may include providing a gas G1 and/or G2 to the substrate SUB, thereby spreading the organic material OM. That is, the organic material OM may have flowability along the first inorganic film IL1 based on application of one or more gases to the substrate SUB.

A support SPT may be disposed below the substrate SUB. The support SPT may define a support opening including a plurality of openings OP1 and OP2. Illustratively, in FIG. 8B, two openings OP1 and OP2 as support openings are defined, but the number of the openings OP1 and OP2 is not limited thereto.

One or more of the openings OP1 and OP2 may be provided in plural such as including a plurality of first openings OP1 and a second opening OP2. The first openings OP1 may be disposed below the first portion PT1 and the 2-1 portion PT2-1. The second opening OP2 may be disposed below the 2-2 portion PT2-2.

A first gas G1 may be sprayed from the first openings OP1 and provided below the substrate SUB. The first gas G1 may be provided below the first portion PT1 and the 2-1 portion PT2-1. The first gas G1 may be provided on a lower surface of the base layer BL.

A second gas G2 may be sprayed from the second opening OP2 and provided below the substrate SUB. The second gas G2 may be provided below the 2-2 portion PT2-2. The second gas G2 may be provided on the lower surface of the base layer BL. Illustratively, the first gas G1 and the second gas G2 may be nitrogen (N₂). The gases may be provide simultaneously with each other, without being limited thereto.

The temperature of the first gas G1 and the temperature of the second gas G2 may be different from each other. The temperature of the first gas G1 may be higher than the temperature of the second gas G2. Illustratively, the temperature of the second gas G2 may be about 20 degrees Celsius (° C.) to about 30° C.

When the first gas G1 and the second gas G2 are provided to a lower portion of the substrate SUB, the temperature of the first portion PT1 and the 2-1 portion PT2-1 which have received heat from the first gas G1 may increase. The temperature of the 2-2 portion PT2-2 which has received heat from the second gas G2 may increase. The temperature of the first portion PT1 and the temperature of the 2-1 portion PT2-1 may be higher than the temperature of the 2-2 portion PT2-2.

The heat of the first gas G1 and the heat of the second gas G2 may be transferred to the organic material OM through layers of the substrate SUB respectively at the first portion PT1 and the second portion PT2. The viscosity of the organic material OM which has received the heat may decrease. The surface tension of the organic material OM which has received the heat may decrease. Accordingly, the organic material OM may spread and clump together, such as to define a single body or single layer of the organic material OM.

The temperature of the organic material OM provided on the first portion PT1 and the 2-1 portion PT2-1 may be higher than the temperature of the organic material OM provided on the 2-2 portion PT2-2. The viscosity of the organic material OM disposed on the first portion PT1 and the 2-1 portion PT2-1 may be lower than the viscosity of the organic material OM disposed on the 2-2 portion PT2-2. The surface tension of the organic material OM disposed on the first portion PT1 and the 2-1 portion PT2-1 may be lower than the surface tension of the organic material OM disposed on the 2-2 portion PT2-2.

Accordingly, owing to the different temperatures applied to the different portion areas of the substrate SUB, the fluidity of the organic material OM along the first inorganic film IL1 which is disposed on the first portion PT1 and the 2-1 portion PT2-1 may be greater than the fluidity of the organic material OM along the first inorganic film IL1 which is disposed on the 2-2 portion PT2-2. The organic material OM disposed on the first portion PT1 and the 2-1 portion PT2-1 may have higher spreadability than the organic material OM disposed on the 2-2 portion PT2-2. Therefore, as illustrated in FIG. 8C, an upper surface of the organic material OM disposed on the first portion PT1 and the 2-1 portion PT2-1 may become flat as a direct result of the higher spreadability of the organic material OM at the first portion PT1 and the 2-1 portion PT2-1.

In addition, since the fluidity of the organic material OM is increased by providing the first gas G1 to a lower portion of the first portion PT1, the time taken for the organic material OM disposed on the first portion PT1 to spread may be reduced. Therefore, the manufacturing process time of the display panel DP (see FIG. 7A) may be reduced.

Referring to FIG. 7B, FIG. 8B, and FIG. 8C, if the second gas G2 having the same temperature as the first gas G1 is provided to a lower portion of the 2-2 portion PT2-2, the fluidity of the organic material OM disposed on the 2-2 portion PT2-2 may be increased as compared to application using the temperature of the first gas G1 and the temperature of the second gas G2 being different from each other as discussed above. In the case of the second gas G2 having the same temperature as the first gas G1, if the first height H1 of the 2-2 organic film OL2-2 is constant, the first length L1 of the 2-2 organic film OL2-2 may be increased. Therefore, even though the area of the non-display region NDA of FIG. 5 is reduced, there may be a limitation in reducing the first length L1 of the 2-2 organic film OL2-2.

However, since one or more embodiment includes the temperature of the second gas G2 being lower than the temperature of the first gas G1, the fluidity of the organic material OM disposed on the second portion PT2 may be reduced. Accordingly, the first length L1 of the 2-2 organic film OL2-2 may be reduced. Here, the 2-1 organic film OL2-1 is a first temperature portion of the organic material OM and the 2-2 organic film OL2-2 is a second temperature portion of the organic material OM. Accordingly, the area of the non-display region NDA of FIG. 5 may be easily reduced since flowability of the organic material OM is reduced at an end portion of the second portion PT2.

Referring to FIG. 8C and FIG. 8D, the method for manufacturing a display device DD of the present invention may include irradiating the organic material OM with light L after the organic material OM is spread. Illustratively, the light L may be ultraviolet light. The organic material OM may be cured by the light L. The organic material OM may be cured and form the organic film OL as cured organic material.

After the organic film OL is formed as including the cured organic material, the second inorganic film IL2 may be disposed on the organic film OL. As an inorganic material layer forming the second inorganic film IL2 is provided, the encapsulation layer TFE including the first inorganic film IL1, the organic film OL, and the second inorganic film IL2, which are sequentially stacked, may be formed.

As the second inorganic film IL2 is provided, the display panel DP including the circuit layer DP-CL, the light emitting element layer DP-OL, and the encapsulation layer TFE, which are sequentially stacked, may be formed. The display panel DP may include the display region DA and the non-display region NDA.

The second inorganic film IL2 may cover the organic film OL. The second inorganic film IL2 may cover the flow control dam FDM, the first dam DM1, and the second dam DM2.

Referring to FIG. 8F, the method for manufacturing a display device DD of the present invention may include sequentially stacking the first sensing insulating layer IS-IL1, the first conductive layer IS-CL1 (see FIG. 4), and the second sensing insulating layer IS-IL2 on the display panel DP. For example, the first sensing insulating layer IS-IL1 may be formed on the display panel DP, and then the first conductive layer IS-CL1 may be formed on the first sensing insulating layer IS-IL1. FIG. 8F exemplarily illustrates the second connectors CP2 and the first sensors SP1, which are part of the first conductive layer IS-CL1. In an embodiment, the first conductive layer IS-CL1 may include the first sensors SP1, the second sensors SP2, and the second connectors CP2. After the first conductive layer IS-CL1 is formed, the second sensing insulating layer IS-IL2 may be formed on the first conductive layer IS-CL1. The second sensing insulating layer IS-IL2 may cover the first sensors SP1, the second sensors SP2, and the second connectors CP2.

Referring to FIG. 8G, the method for manufacturing a display device DD of the present invention may include forming the contact-hole CH in the second sensing insulating layer IS-IL2. A mask MK may be aligned or disposed facing the display panel DP. The mask MK may include a plurality of mask openings M_CH. The mask openings M_CH may be disposed corresponding to a region in which the contact-hole CH of the input sensor ISP is formed. After the mask MK is disposed, at least a portion of the second sensing insulating layer IS-IL2 may be removed by an exposure process and the contact-holes CH may be formed. The first conductive layer IS-CL1 may be exposed to outside the second sensing insulating layer IS-IL2 by the contact-holes CH.

Referring to FIG. 8H, the method for manufacturing a display device DD of the present invention may include sequentially stacking the second conductive layer IS-CL2 (see FIG. 4) and the third sensing insulating layer IS-IL3 on the second sensing insulating layer IS-IL2. For example, the second conductive layer IS-CL2 (see FIG. 4) may be formed on the second sensing insulating layer IS-IL2, and then the third sensing insulating layer IS-IL3 may be formed on the second conductive layer IS-CL2. FIG. 8H exemplarily illustrates the first connector CP1, which is part of the second conductive layer IS-CL2 (see FIG. 4).

Referring to FIG. 8C and FIG. 8H, however, since the temperature of the second gas G2 is lower than the temperature of the first gas G1, the fluidity of the organic material OM disposed on the second portion PT2 may be reduced. At the non-display region NDA, a length of a 2-2 organic film OL2-2 portion in the first direction DR1 which has a thickness smaller than the first height H1 may be reduced. Accordingly, at the display region DA adjacent to the non-display region NDA, the organic film OL having a dielectric constant may reduce noise generated between the circuit layer DP-CL and the input sensor ISP. Therefore, touch reliability of the display device DD (see FIG. 1) may be improved.

According to an embodiment of the present invention, the temperature of a gas provided to an organic material layer in a display region DA may be higher than the temperature of a gas provided to the organic material layer in a non-display region NDA. Accordingly, the viscosity of an organic material OM disposed on the display region DA may be lower than the viscosity of an organic material OM disposed on the non-display region NDA. Therefore, the spreading of the organic material OM which is on the display region DA increases, so that the flatness of the organic material OM on the display region DA may be improved. In addition, the spreading of the organic material OM on the non-display region NDA may be reduced, especially at an edge portion of the non-display region NDA, so that the planar area of the organic material OM on the non-display region NDA may be reduced.

Although the invention has been described with reference to embodiments the invention, it will be understood by those skilled in the art that various changes in form and details may be made therein without departing from the spirit and scope of the invention as set forth in the following claims. In addition, the embodiments disclosed in the invention are not intended to limit the technical spirit of the invention, and all technical concepts falling within the scope of the following claims and equivalents thereof are to be construed as being included in the scope of the invention.

The display device DD according to embodiments of the present disclosure may be applied to various electronic devices. An electronic device according to an embodiment of the present disclosure may include the display device DD described herein, and may further include a module or device having additional functions in addition to the display device DD.

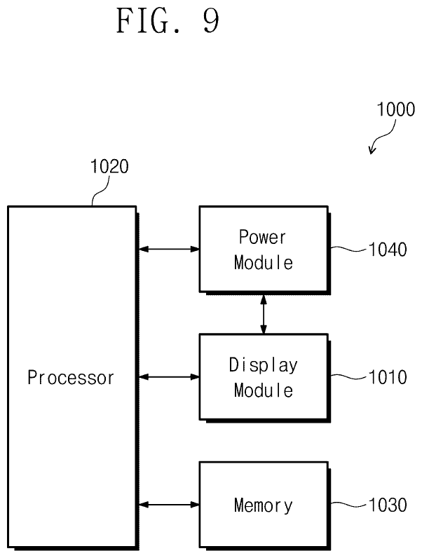

FIG. 9 is a block diagram illustrating an electronic device 1000 according to an embodiment of the present disclosure.

Referring to FIG. 9, an electronic device 1000 may include a display module 1010, a processor 1020, a memory 1030, and a power module 1040.

The processor 1020 may include at least one of a central processing unit (CPU), an application processor (AP), a graphic processing unit (GPU), a communication processor (CP), an image signal processor (ISP), and a controller.

The memory 1030 may store data information necessary for an operation of the processor 1020 or the display module 1010. When the processor 1020 executes an application stored in the memory 1030, an image data signal and/or an input control signal may be transmitted to the display module 1010, and the display module 1010 may process the received signal and output image information through a display screen.

The power module 1040 may include a power supply module such as a power adapter, a battery device, or the like and a power conversion module which converts power supplied by the power supply module to generate power necessary for an operation of the electronic device 1000.

At least one of the components of the electronic device 1000 described above may be included in the display device DD according to embodiments described above. In addition, some of individual modules functionally included in one module may be included in the display device DD, and others may be provided separately from the display device DD. For example, the display device DD may include the display module 1010, and the processor 1020, the memory 1030, and the power module 1040 may be provided in form of other devices in the electronic device 1000 other than the display device DD.

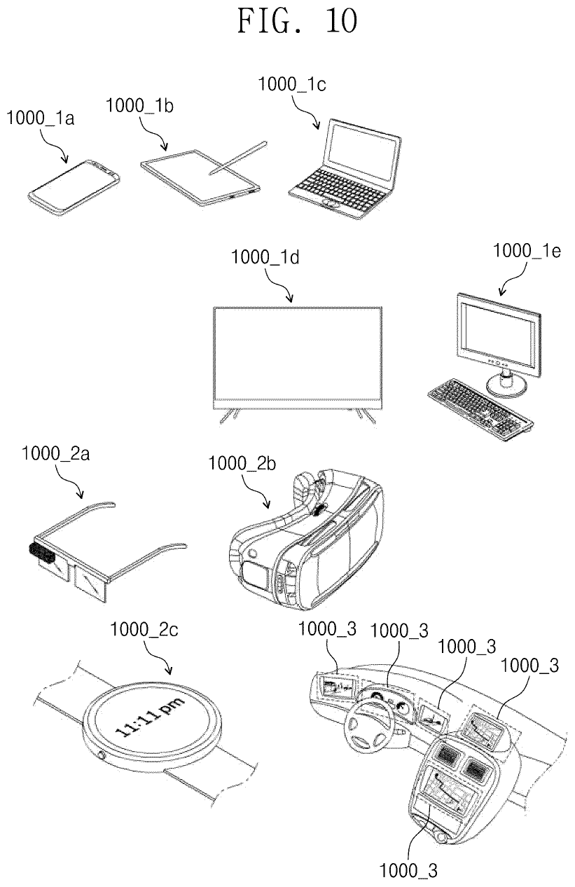

FIG. 10 is a schematic view of electronic devices according to embodiments of the present disclosure.

Referring to FIG. 10, various electronic devices to which the display device DD according to embodiments of the present disclosure are applied may include not only an image display electronic device, but also a wearable electronic device including a display module, a vehicle electronic device 1000_3 including a display module, or the like. The image display electronic device may be a smartphone 1000_1a, a tablet PC 1000_1b, a laptop 1000_1c, a TV 1000_1d, a desk monitor 1000_1e, or the like. The wearable electronic device may be smart glasses 1000_2a, a head mounted display 1000_2b, a smart watch 1000_2c, or the like. The vehicle electronic device 1000_3 may be a center information display (CID) disposed on a dashboard and center fascia of a vehicle, a room mirror display, or the like.

In an embodiment, a method for providing an electronic device includes providing a display device including a display region including a display element and a non-display region which extends from the display region, and a substrate in the display region and in the non-display region, the substrate including a base layer, a circuit layer and a display element layer sequentially stacked, providing an organic material on the substrate, in the display region and the non-display region, spreading the organic material along the display element layer to provide an organic material layer (e.g., OM) in the display region and the non-display region; and irradiating the organic material layer with light to provide a cured organic material layer (e.g., OL) in the display region and the non-display region. A temperature of the gas provided in the display region and a temperature of the gas provided in the non-display region are different from each other.

In an embodiment, the method may include applying gas or heat to the substrate having the organic material thereon, the applying of the gas or the heat spreading the organic material along the first inorganic encapsulation layer to provide an organic material layer in the display region and the non-display region. The spreading of the organic material by the providing of the heat may provide both the organic material layer in the display region having a flat upper surface, and the organic material layer in the non-display region having an inclined upper surface.

The providing of the gas and/or the heat may define a viscosity or surface tension of the organic material, where the viscosity of the organic material in the display region may be lower than the viscosity of the organic material in the non-display region, and the surface tension of the organic material in the display region may be smaller than the surface tension of the organic material in the non-display region.

In an embodiment, the cured organic material layer may have a height from a plane of the display element layer as a reference plane, and the height of a portion of the cured organic material layer which is furthest from the display region may be smaller than the height of a portion of the cured organic material layer overlapping the display region.

In an embodiment, the non-display region extends from the display region in a first direction, and the substrate further includes in the non-display region a first dam which is spaced apart in the first direction from a flow control dam and further from the display region in the first direction than the flow control dam. The flow control dam may include opposing sides along the first direction, one side among the opposing sides of the flow control dam being closer to the display region, and the spreading of the organic material by the providing of the gas may dispose the organic material facing the one side of the flow control dam.

In an embodiment, the method may further include providing an inorganic encapsulation film (e.g., IL2) of the display device which covers the cured organic material layer of the substrate, and providing an input sensor of the display device on the inorganic encapsulation film of the substrate. Here, the inorganic encapsulation film may covers the flow control dam and the first dam of the substrate.

In an embodiment, the method may further include providing a power module which supplies power to the display device as a display module, without being limited thereto.

What is claimed is:

1. A method for providing an electronic device, the method comprising:
providing a display device comprising:
a display region including a display element and a non-display region which extends from the display region, and
a substrate in the display region and in the non-display region, the substrate comprising a base layer, a circuit layer and a display element layer sequentially stacked;
providing an organic material on the substrate, in the display region and the non-display region;
providing a gas to the substrate having the organic material thereon, the providing of the gas spreading the organic material along the display element layer to provide an organic material layer in the display region and the non-display region; and
irradiating the organic material layer with light to provide a cured organic material layer in the display region and the non-display region,
wherein a temperature of the gas provided in the display region and a temperature of the gas provided in the non-display region are different from each other.

2. The method of claim 1, wherein the temperature of the gas provided in the display region is higher than the temperature of the gas provided in the non-display region.

3. The method of claim 2, wherein the temperature of the gas provided in the non-display region is about 20 degrees Celsius to about 30 degrees Celsius.

4. The method of claim 2, wherein
the providing of the gas defines a viscosity of the organic material, and
the viscosity of the organic material in the display region is lower than the viscosity of the organic material in the non-display region.

5. The method of claim 4, wherein
the providing of the gas further defines a surface tension of the organic material, and
the surface tension of the organic material in the display region is smaller than the surface tension of the organic material in the non-display region.

6. The method of claim 4, wherein the spreading of the organic material by the providing of the gas provides the organic material layer in the display region having a flat upper surface.

7. The method of claim 6, wherein the spreading of the organic material by the providing of the gas further provides the organic material layer in the non-display region having an inclined upper surface.

8. The method of claim 2, wherein
the cured organic material layer has a height from a plane of the display element layer, and
the height of a portion of the cured organic material layer which is furthest from the display region is smaller than the height of a portion of the cured organic material layer overlapping the display region.

9. The method of claim 1, wherein the gas includes nitrogen.

10. The method of claim 1, wherein
the non-display region extends from the display region in a first direction, and
the substrate further comprises in the non-display region:
a flow control dam, and
a first dam which is spaced apart in the first direction from the flow control dam and further from the display region in the first direction than the flow control dam.

11. The method of claim 10, wherein
the flow control dam includes opposing sides along the first direction, one side among the opposing sides of the flow control dam being closer to the display region, and
the spreading of the organic material by the providing of the gas disposes the organic material facing the one side of the flow control dam.

12. The method of claim 10, further comprising providing an inorganic encapsulation film of the display device which covers the cured organic material layer of the substrate.

13. The method of claim 12, further comprising providing an input sensor of the display device on the inorganic encapsulation film of the substrate.

14. The method of claim 12, wherein the inorganic encapsulation film covers the flow control dam and the first dam of the substrate.

15. A method for providing an electronic device, the method comprising:
providing a display device comprising:
a display region including a display element and a non-display region which extends from the display region, and
a substrate in the display region and in the non-display region, the substrate comprising a base layer, a circuit layer, a display element layer and a first inorganic encapsulation film sequentially stacked;
providing an organic material on the substrate, in the display region and the non-display region;
applying heat to the substrate having the organic material thereon, the applying of the heat spreading the organic material along the first inorganic encapsulation layer to provide an organic material layer in the display region and the non-display region; and
irradiating the organic material layer with light to provide a cured organic material layer in the display region and the non-display region,
wherein a temperature of the heat applied in the display region is higher than a temperature of the heat applied in the non-display region.

16. The method of claim 15, wherein the applying of the heat to the substrate comprises providing a gas to the substrate having the organic material thereon.

17. The method of claim 16, wherein a temperature of the gas provided in the display region is higher than a temperature of the gas provided in the non-display region.

18. The method of claim 17, wherein the temperature of the gas provided in the non-display region is about 20 degrees Celsius to about 30 degrees Celsius.

19. The method of claim 15, wherein
the providing of the heat defines a viscosity of the organic material, and
the viscosity of the organic material in the display region is lower than the viscosity of the organic material in the non-display region.

20. The method of claim 19, wherein the spreading of the organic material by the providing of the heat provides both:
the organic material layer in the display region having a flat upper surface; and
the organic material layer in the non-display region having an inclined upper surface.
